(19) United States
(12) Patent Application Publication
(10) Pub. No.: US 2026/0223397 A1
(43) Pub. Date: Jul. 30, 2026

(54) SEMICONDUCTOR DEVICE

(71) Applicant: ROHM CO., LTD., Kyoto-shi (JP)

(72) Inventors: Rogosu WAGURI, Kyoto-shi (JP); Seigo MORI, Kyoto-shi (JP)

(73) Assignee: ROHM CO., LTD., Kyoto-shi (JP)

(21) Appl. No.: 19/630,541

(22) Filed: Mar. 27, 2026

Related U.S. Application Data
(63) Continuation of application No. PCT/JP2024/033449, filed on Sep. 19, 2024.

(30) Foreign Application Priority Data
Oct. 16, 2023 (JP) 2023-178289

(51) Int. Cl. H10D 30/66; H10D 62/10; H10D 62/832

(52) U.S. Cl. CPC H10D 30/668; H10D 62/109; H10D 62/127; H10D 62/8325

(57) ABSTRACT

A semiconductor device includes a chip having a principal surface, a first conductivity type drift region formed at a surface layer portion of the principal surface, a trench electrode type gate structure formed on the principal surface such as to be placed in the drift region, and a second conductivity type well region formed along a bottom wall of the gate structure in a region below the gate structure in the drift region, wherein the well region includes a plurality of first well regions each of which is a first well region having a first bottom portion having a first depth and which are formed at an interval of a first interval from each other in a depth direction of the gate structure, and the first well regions adjacent each other face each other in the depth direction of the gate structure across a portion of the drift region.

### CROSS-REFERENCE TO RELATED APPLICATIONS

The present application is a continuation application of PCT Application No. PCT/JP2024/033449, filed on Sep. 19, 2024, which corresponds to Japanese Patent Application No. 2023-178289, filed with the Japan Patent Office on Oct. 16, 2023, and the entire disclosure of the application is incorporated herein by reference.

### TECHNICAL FIELD

The present disclosure relates to a semiconductor device.

### BACKGROUND ART

U.S. Patent Application Publication No. 2010/0224932 discloses a semiconductor device including a semiconductor substrate, a semiconductor region, a body region, a gate trench, a gate insulating film, a gate electrode, and a p-type diffusion region. The semiconductor region is formed on the upper surface side of the semiconductor substrate. The body region is formed closer to the upper surface of the semiconductor substrate than to the semiconductor region.

The gate trench is formed on the upper surface of the semiconductor substrate, and penetrates through the body region. The gate insulating film covers the wall surface of the gate trench. The gate electrode is embedded in the gate trench through the gate insulating film. The p-type diffusion region is formed along the bottom wall of the gate trench in the semiconductor region.

### BRIEF DESCRIPTION OF DRAWINGS

FIG. 1 is a plan view showing a semiconductor device according to a first preferred embodiment of the present disclosure.

FIG. 2 is a cross-sectional view taken along line II-II shown in FIG. 1.

FIG. 3 is a plan view showing a layout example of a chip.

FIG. 4 is an enlarged view of a portion surrounded by an alternate long and short dash line IV of FIG. 3.

FIG. 5 is a cross-sectional view taken along line V-V shown in FIG. 4.

FIG. 6 is a cross-sectional view taken along line VI-VI shown in FIG. 4.

FIG. 7 is a cross-sectional view taken along line VII-VII shown in FIG. 4.

FIG. 8 is an enlarged view of a portion surrounded by an alternate long and short dash line VIII of FIG. 5.

FIG. 9 is an enlarged view of a portion surrounded by an alternate long and short dash line IX of FIG. 6.

FIG. 10 is a cross-sectional view of a semiconductor device according to a reference example, which corresponds to FIG. 6.

FIG. 11 is a cross-sectional view of a semiconductor device according to a reference example, which corresponds to FIG. 7.

FIG. 12 is a plan view showing a layout example of a chip according to a second preferred embodiment of the present disclosure, which corresponds to FIG. 4.

FIG. 13 is a cross-sectional view taken along line XIII-XIII shown in FIG. 12.

FIG. 14 is a cross-sectional view taken along line XIV-XIV shown in FIG. 12.

FIG. 15 is a cross-sectional view taken along line XV-XV shown in FIG. 12.

FIG. 16 is a cross-sectional view taken along line XVI-XVI shown in FIG. 12.

FIG. 17 is an enlarged view of a portion surrounded by an alternate long and short dash line XVII of FIG. 15.

FIG. 18 is a cross-sectional view of a semiconductor device according to a first modification example, which corresponds to FIG. 16.

FIG. 19 is a cross-sectional view of a semiconductor device according to a second modification example, which corresponds to FIG. 9.

FIG. 20 is a cross-sectional view of a semiconductor device according to a third modification example, which corresponds to FIG. 5.

FIG. 21 is a cross-sectional view of the semiconductor device according to the third modification example, which corresponds to FIG. 6.

FIG. 22 is a cross-sectional view of a semiconductor device according to a fourth modification example.

FIG. 23 is a cross-sectional view of the semiconductor device according to the fourth modification example.

FIG. 24 is a cross-sectional view of a semiconductor device according to a fifth modification example.

FIG. 25 is a cross-sectional view of the semiconductor device according to the fifth modification example.

FIG. 26 is a cross-sectional view of a semiconductor device according to a sixth modification example, which corresponds to FIG. 5.

FIG. 27 is a cross-sectional view of the semiconductor device according to the sixth modification example, which corresponds to FIG. 6.

### DETAILED DESCRIPTION

Concrete configurations will be hereinafter described in detail with reference to the accompanying drawings. All of the accompanying drawings are schematic views, and are not strictly shown, and do not coincide with each other in relative positional relationship, scale reduction, ratio, angle, etc. The same reference sign is assigned to a constituent that corresponds to each constituent in the accompanying drawings, and a duplicated description of this constituent is omitted or simplified. A description of a constituent, which has not yet been omitted or simplified, is applied to a corresponding constituent a description of which has been omitted or simplified.

When the term “substantially” is used in this description, this term includes a numerical error (configuration error) falling within the range of ±10% based on a numerical value (configuration) that is a targeted value for comparison, in addition to a numerical value (configuration) equal to the targeted numerical value (configuration). Although the terms “first,” “second,” “third,” etc., are hereinafter used, these terms are signs assigned to the name of each constituent in order to clarify the explanatory order, and are not assigned in order to restrict the name of each constituent.

Although the conductivity type of a semiconductor (impurity) is hereinafter shown by use of a “p-type” or an “n-type,” the “n-type” may be referred to as a “first conductivity type,” and the “p-type” may be referred to as a “second conductivity type.” As a matter of course, the “p-type” may be referred to as the “first conductivity type,” and the “n-type” may be referred to as the “second conductivity type.” The “p-type” is a conductivity type resulting from a trivalent element, and the “n-type” is a conductivity type resulting from a quinquevalent element. The trivalent element is at least one among boron, aluminum, gallium, and indium. The quinquevalent element is at least one among nitrogen, phosphorus, arsenic, antimony, and bismuth.

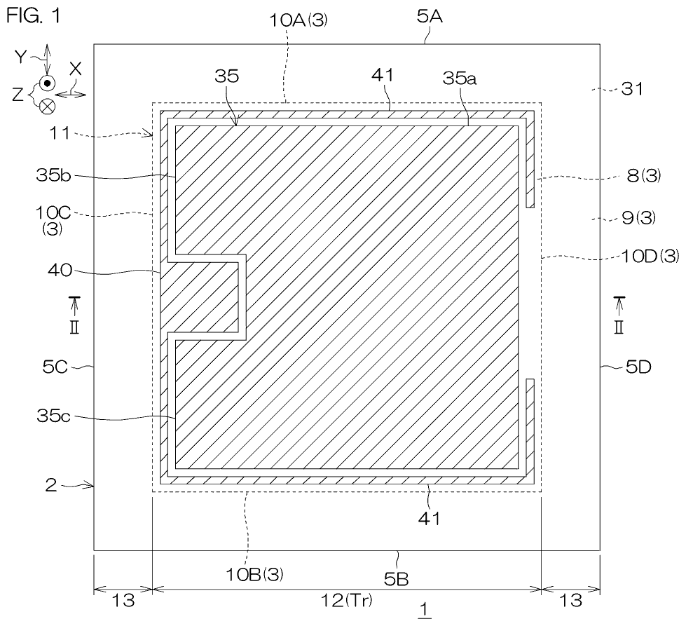

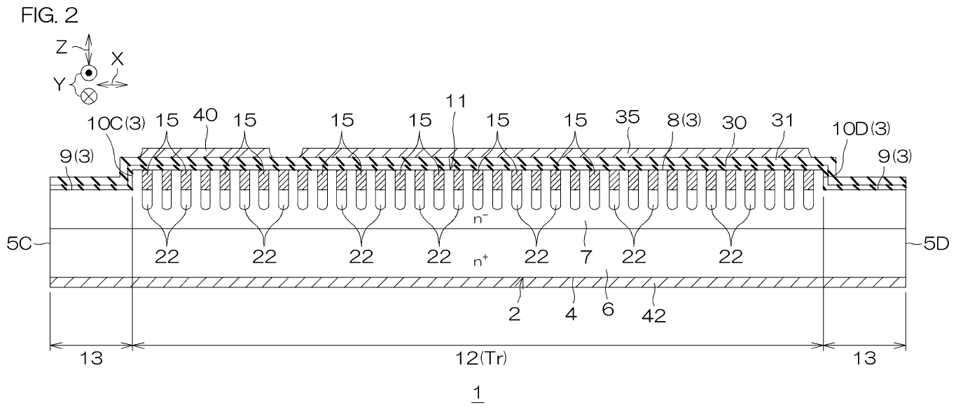

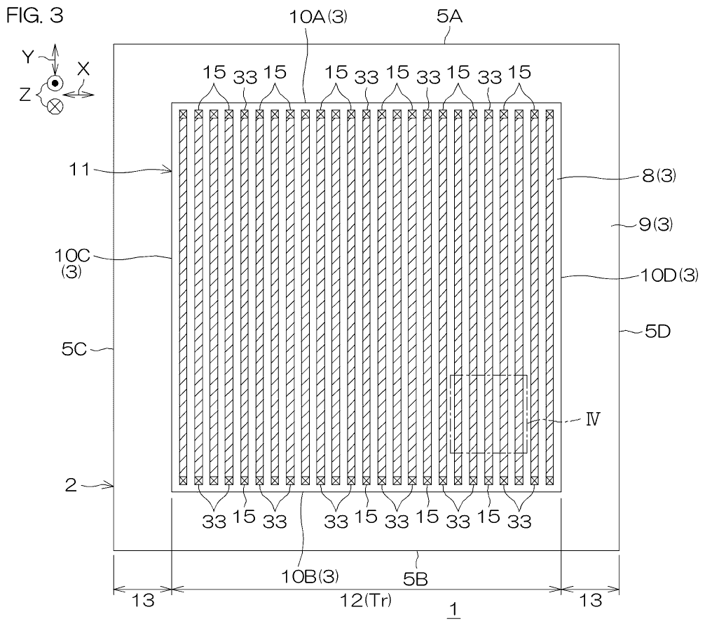

FIG. 1 is a plan view showing a semiconductor device 1 according to a first preferred embodiment of the present disclosure. FIG. 2 is a cross-sectional view taken along line II-II shown in FIG. 1. FIG. 3 is a plan view showing a layout example of a chip 2.

Referring to FIG. 1 to FIG. 3, the semiconductor device 1 is a semiconductor switching device having an insulated-gate type transistor structure Tr as an example of a device structure. The transistor structure Tr has a vertical structure. The semiconductor device 1 is an SiC semiconductor device having the chip 2 including an SiC monocrystal. The chip 2 may be referred to as an “SiC chip” or as a “semiconductor chip.”

In this preferred embodiment, the chip 2 is constituted of a hexagonal SiC monocrystal, and is formed in a rectangular parallelepiped shape. The hexagonal SiC monocrystal has a plurality of polytypes including 2H (Hexagonal)-SiC monocrystal, 4H—SiC monocrystal, 6H—SiC monocrystal, etc. Although an example in which the chip 2 is constituted of 4H—SiC monocrystal is shown in this preferred embodiment, the chip 2 may be constituted of another polytype.

The chip 2 has a first principal surface (principal surface) 3 on one side, a second principal surface 4 on the other side, and first to fourth side surfaces 5A to 5D connecting the first principal surface 3 and the second principal surface 4. The first principal surface 3 and the second principal surface 4 are each formed in a quadrangular shape in a plan view seen from a vertical direction Z (which is hereinafter referred to simply as the “plan view”). The vertical direction Z is also a thickness direction of the chip 2 or a normal direction of the first principal surface 3 (second principal surface 4). The first principal surface 3 and the second principal surface 4 may be each formed in a square shape or in a rectangular shape in the plan view.

Preferably, the first principal surface 3 and the second principal surface 4 are each formed by a c-plane of an SiC monocrystal. In this case, preferably, the first principal surface 3 is formed by a silicon plane ((0001) plane) of the SiC monocrystal, and the second principal surface 4 is formed by a carbon plane ((000-1) plane) of the SiC monocrystal.

The first side surface 5A and the second side surface 5B extend in a first direction X along the first principal surface 3, and face a second direction Y intersecting the first direction X along the first principal surface 3. In detail, the second direction Y perpendicularly intersects the first direction X. The third side surface 5C and the fourth side surface 5D extend in the second direction Y, and face the first direction X.

In this preferred embodiment, the first direction X is an m-axial direction ([1-100] direction) of the SiC monocrystal, and the second direction Y is an a-axial direction ([11-20] direction) of the SiC monocrystal. As a matter of course, the first direction X may be the a-axial direction of the SiC monocrystal, and the second direction Y may be the m-axial direction of the SiC monocrystal. Hereinafter, a direction extending along the first principal surface 3 is expressed at times as a “horizontal direction,” and a surface along the first principal surface 3 is expressed at times as a “horizontal surface.” The horizontal direction is also an XY flat surface (horizontal surface) formed by the first direction X and the second direction Y, and perpendicularly intersects the vertical direction Z.

The chip 2 (first principal surface 3 and second principal surface 4) has an off angle that is inclined at a predetermined angle with respect to the c-plane of the SiC monocrystal in a predetermined off direction. The c-axis ((0001) axis) of the SiC monocrystal is inclined by just the off angle in the off direction from a vertical line. Additionally, the c-plane of the SiC monocrystal is inclined by just the off angle with respect to the horizontal surface.

Preferably, the off direction is the a-axial direction (second direction Y) of the SiC monocrystal. The off angle may be more than 0° and not more than 10°. The off angle may have a value falling within at least one range among more than 0° and not more than 1°, not less than 1° and not more than 2.5°, not less than 2.5° and not more than 5°, not less than 5° and not more than 7.5°, and not less than 7.5° and not more than 10°.

Preferably, the off angle is equal to or less than 5°. Particularly preferably, the off angle is not less than 2° and not more than 4.5°. Typically, the off angle is set within the range of 4°±0.1°. This description does not exclude a configuration in which the off angle is 0° (the first principal surface 3 is a just surface with respect to the c-plane).

The semiconductor device 1 includes an n-type first semiconductor region 6 formed at a surface layer portion of the second principal surface 4 of the chip 2. A drain potential that is a first potential (high potential) is applied to the first semiconductor region 6. The first semiconductor region 6 may be referred to as a “semiconductor layer,” a “first semiconductor layer,” a “drain region,” etc. The first semiconductor region 6 may have an n-type impurity concentration of not less than 1×10¹⁴ cm⁻³ and not more than 1×10²¹ cm⁻³.

The first semiconductor region 6 is formed in a layer shape extending along the second principal surface 4, and is exposed from the second principal surface 4 of the chip 2 and from the first to fourth side surfaces 5A to 5D of the chip 2. The first semiconductor region 6 is constituted of an n-type semiconductor layer in this preferred embodiment. In detail, the first semiconductor region 6 is constituted of a substrate (SiC substrate) including an SiC monocrystal (semiconductor monocrystal), and forms the second principal surface 4 of the chip 2 and the first to fourth side surfaces 5A to 5D of the chip 2. The first semiconductor region 6 has the off direction and the off angle mentioned above.

The first semiconductor region 6 may have a thickness of not less than 10 μm and not more than 500 μm. The thickness of the first semiconductor region 6 may have a value falling within at least one range of not less than 10 μm and not more than 50 μm, not less than 50 μm and not more than 100 μm, not less than 100 μm and not more than 150 μm, not less than 150 μm and not more than 200 μm, not less than 200 μm and not more than 300 μm, not less than 300 μm and not more than 400 μm, and not less than 400 μm and not more than 500 μm.

The semiconductor device 1 includes an n-type second semiconductor region (drift region) 7 formed at a surface layer portion of the first principal surface 3 of the chip 2. The second semiconductor region 7 may be referred to as a “semiconductor layer,” a “second semiconductor layer,” a “drift region,” etc. The second semiconductor region 7 has an n-type impurity concentration less than the n-type impurity concentration of the first semiconductor region 6. The n-type impurity concentration of the second semiconductor region 7 may be not less than 1×10¹⁴ cm⁻³ and not more than 1×10¹⁸ cm⁻³.

The second semiconductor region 7 is formed in a layer shape extending along the first principal surface 3, and is electrically connected to the first semiconductor region 6. The second semiconductor region 7 is exposed from the second principal surface 4 of the chip 2 and from the first to fourth side surfaces 5A to 5D of the chip 2. The second semiconductor region 7 is constituted of an n-type semiconductor layer in this preferred embodiment.

In detail, the second semiconductor region 7 is constituted of an epitaxial layer (SiC epitaxial layer) including an SiC monocrystal (semiconductor monocrystal), and forms the first principal surface 3 of the chip 2 and the first to fourth side surfaces 5A to 5D of the chip 2. The second semiconductor region 7 (epitaxial layer) has the off direction and the off angle mentioned above. Preferably, the second semiconductor region 7 has a thickness less than the thickness of the first semiconductor region 6. The thickness of the second semiconductor region 7 may be larger than the thickness of the first semiconductor region 6. The thickness of the second semiconductor region 7 may be not less than 5 μm and not more than 50 μm.

The semiconductor device 1 includes a first surface portion 8, a second surface portion 9, and first to fourth connecting surface portions 10A to 10D that are formed on the first principal surface 3. The first surface portion 8, the second surface portion 9, and the first to fourth connecting surface portions 10A to 10D demarcate a mesa 11 in the first principal surface 3. The first surface portion 8, the second surface portion 9, and the first to fourth connecting surface portions 10A to 10D (mesa 11) may be each regarded as a constituent of the chip 2 (first principal surface 3).

The first surface portion 8 may be referred to as an “active surface,” the second surface portion 9 may be referred to as an “outer surface,” the first to fourth connecting surface portions 10A to 10D may be referred to as “connecting surfaces,” and the mesa 11 may be referred to as an “active mesa.”

The first surface portion 8 is formed at intervals inward from peripheral edges of the first principal surface 3 (from the first to fourth side surfaces 5A to 5D). The first surface portion 8 has a flat surface extending in the horizontal direction, and is formed by the c-plane (Si plane). In this preferred embodiment, the first surface portion 8 is formed in a quadrangular shape having four sides parallel to the first to fourth side surfaces 5A to 5D in the plan view. Preferably, the plane area of the first surface portion 8 is not less than 50% and not more than 90% of the plane area of the first principal surface 3.

The second surface portion 9 is placed on the peripheral edge portion side of the first principal surface 3 with respect to the first surface portion 8, and is recessed in the thickness direction of the chip 2 (toward the second principal surface 4 side) from a height position of the first surface portion 8. The second surface portion 9 extends in a band shape along the first surface portion 8 in the plan view, and is formed in an annular shape (in detail, in a quadrangle annular shape) surrounding the first surface portion 8. The second surface portion 9 is continuous with the first to fourth side surfaces 5A to 5D.

The second surface portion 9 is formed in substantially parallel with respect to the first surface portion 8, and has a flat surface extending in the horizontal direction. The second surface portion 9 is formed by the c-plane (Si plane) in this preferred embodiment. The second surface portion 9 is formed in the second semiconductor region 7 at an interval from the first semiconductor region 6. The second surface portion 9 is recessed at a depth less than the thickness of the second semiconductor region 7, and exposes the second semiconductor region 7.

The second surface portion 9 has a depth of not less than 0.1 μm and not more than 3 μm. The depth of the second surface portion 9 may have a value falling within at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. Preferably, the depth of the second surface portion 9 is not less than 1.5 μm and not more than 2.5 μm.

The first to fourth connecting surface portions 10A to 10D extend in the vertical direction Z, and are connected to the first surface portion 8 and to the second surface portion 9. The first connecting surface portion 10A is placed on the first side surface 5A side, the second connecting surface portion 10B is placed on the second side surface 5B side, the third connecting surface portion 10C is placed on the third side surface 5C side, and the fourth connecting surface portion 10D is placed on the fourth side surface 5D side. The first connecting surface portion 10A and the second connecting surface portion 10B extend in the first direction X, and face the second direction Y. The third connecting surface portion 10C and the fourth connecting surface portion 10D extend in the second direction Y, and face the first direction X.

The first to fourth connecting surface portions 10A to 10D may extend substantially perpendicularly between the first surface portion 8 and the second surface portion 9, and may demarcate the mesa 11 having a quadrilateral prism shape. The first to fourth connecting surface portions 10A to 10D may be inclined obliquely downward from the first surface portion 8 toward the second surface portion 9, and may demarcate the mesa 11 having a truncated quadrilateral pyramid shape. The first to fourth connecting surface portions 10A to 10D may be inclined at an angle exceeding 90° and being not more than 135° with respect to the first surface portion 8.

In this way, the mesa 11 is demarcated in a projecting shape in the second semiconductor region 7 in the first principal surface 3. The mesa 11 is formed only in the second semiconductor region 7, and is not formed in the first semiconductor region 6.

The semiconductor device 1 includes an active region 12 set in the chip 2. The active region 12 includes a device structure (transistor structure Tr), and is a region in which an output current (drain current) is generated. The active region 12 is set in an inner portion of the chip 2. In detail, the active region 12 is set in the first surface portion 8.

The semiconductor device 1 includes an outer peripheral region 13 set outside the active region 12 in the chip 2. The outer peripheral region 13 is a region that does not include a device structure (transistor structure Tr). The outer peripheral region 13 is set in a peripheral edge portion of the chip 2. In detail, the outer peripheral region 13 is set in the second surface portion 9. The outer peripheral region 13 is set in a region between a peripheral edge of the first surface portion 8 and a peripheral edge of the second surface portion 9 in the plan view.

An arrangement in the active region 12 is hereinafter shown. The semiconductor device 1 includes a plurality of gate structures 15 of a trench type (trench electrode type) formed on the first principal surface 3 (first surface portion 8). The gate structure 15 may be referred to as a “trench gate structure,” a “trench structure,” etc. A gate potential is applied as a control potential to the plurality of gate structures 15.

Referring to FIG. 2 and FIG. 3, the plurality of gate structures 15 are formed at the first surface portion 8 at intervals inward from the peripheral edges of the first surface portion 8 (first to fourth connecting surface portions 10A to 10D). The plurality of gate structures 15 are arrayed at an interval from each other in the first direction X in the plan view, and are each formed in a band shape extending in the second direction Y. The plurality of gate structures 15 are arrayed in a stripe shape extending in the second direction Y (depth direction) in the plan view. The plurality of gate structures 15 may be arrayed at an interval of not less than 0.25 μm and not more than 3 μm from each other.

The plurality of gate structures 15 are placed in the second semiconductor region 7. The plurality of gate structures 15 are formed at intervals toward the first principal surface 3 side from a bottom portion of the second semiconductor region 7, and face the first semiconductor region 6 across a part of the second semiconductor region 7. The plurality of gate structures 15 are formed substantially perpendicularly with respect to the first principal surface 3 (first surface portion 8).

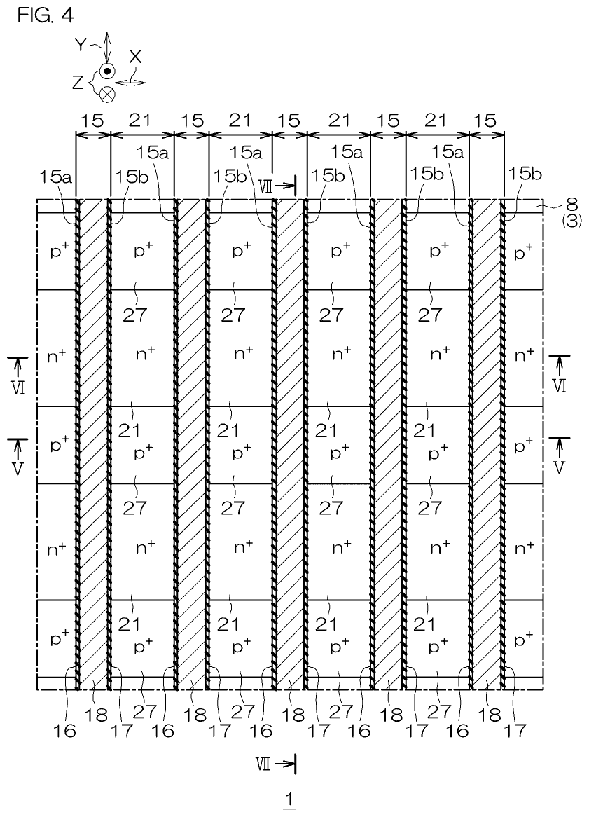

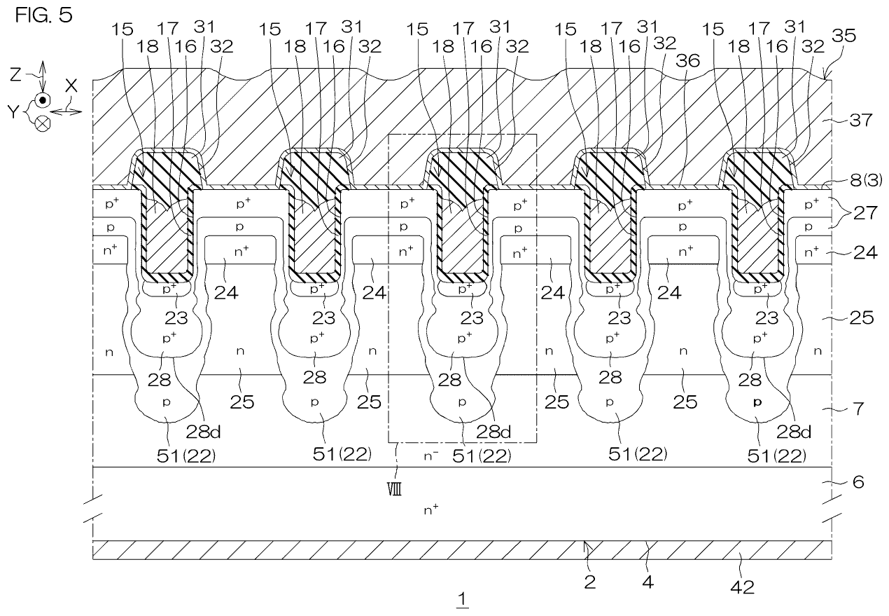

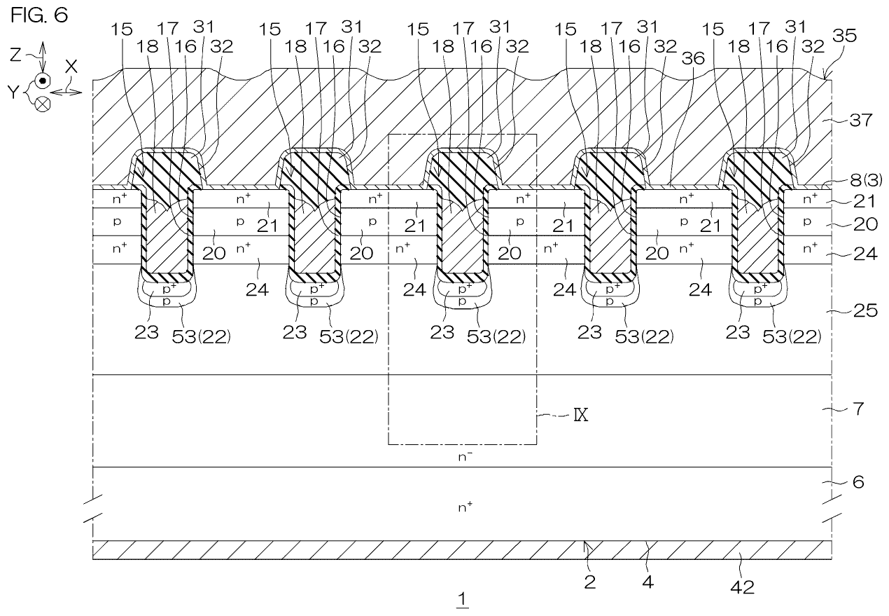

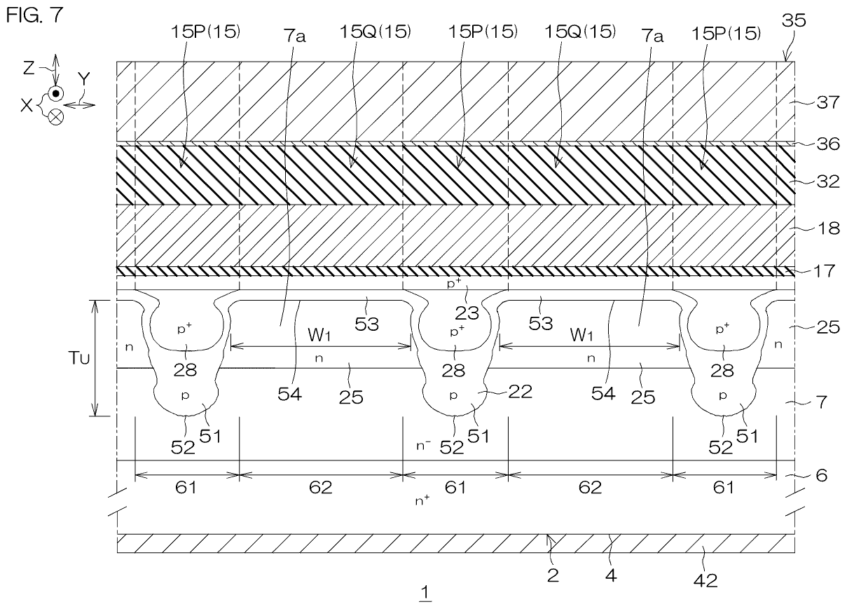

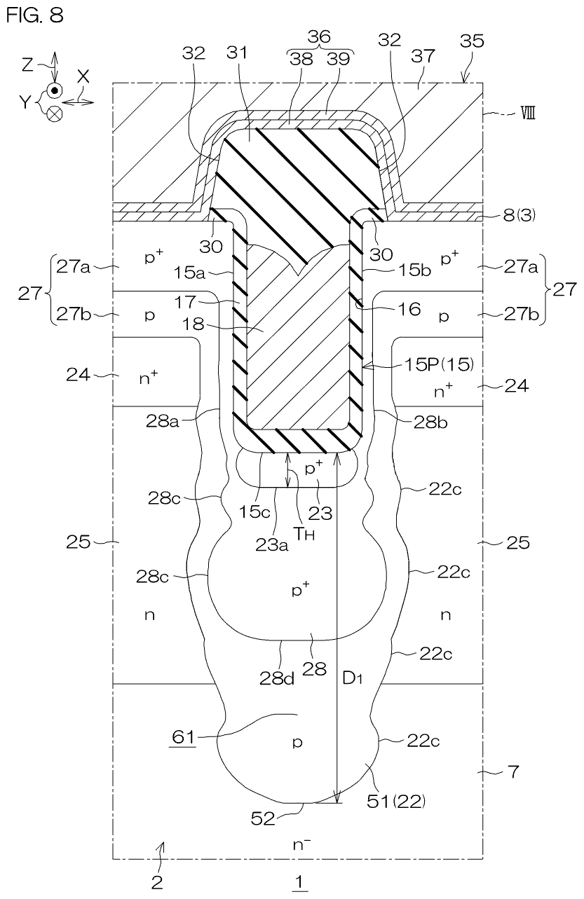

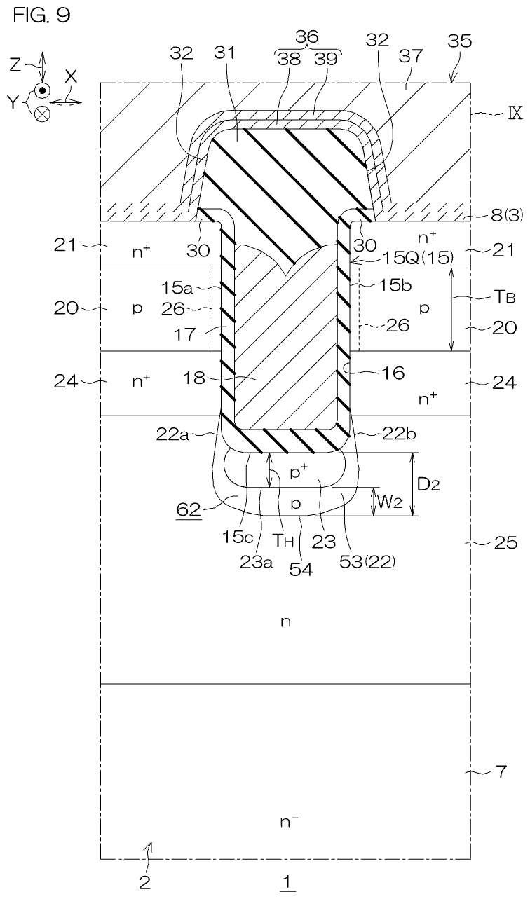

FIG. 4 is an enlarged view of a portion surrounded by an alternate long and short dash line IV of FIG. 3. FIG. 5 is a cross-sectional view taken along line V-V shown in FIG. 4. FIG. 6 is a cross-sectional view taken along line VI-VI shown in FIG. 4. FIG. 7 is a cross-sectional view taken along line VII-VII shown in FIG. 4. FIG. 8 is an enlarged view of a portion surrounded by an alternate long and short dash line VIII of FIG. 5. FIG. 9 is an enlarged view of a portion surrounded by an alternate long and short dash line IX of FIG. 6. Referring to FIG. 4 to FIG. 6, FIG. 8, and FIG. 9 in addition to FIG. 2 and FIG. 3, an arrangement of the plurality of gate structures 15 will be continuously described.

In a cross-sectional view, each of the plurality of gate structures 15 has a first side wall 15a on one side (third side surface 5C side) in the first direction X, a second side wall 15b on the other side (fourth side surface 5D side) in the first direction X, and a bottom wall 15c connecting the first side wall 15a and the second side wall 15b as shown in FIG. 8 and FIG. 9.

The first side wall 15a and the second side wall 15b are each formed by an a-plane ((11-20) plane) of the SiC monocrystal. As a matter of course, the first side wall 15a and the second side wall 15b may be each formed by an m-plane ((1-100) plane) of the SiC monocrystal in accordance with the depth direction (second direction Y) of the gate structure 15. The first side wall 15a and the second side wall 15b are formed substantially perpendicularly with respect to the first principal surface 3. An inclination angle (absolute value) of the first side wall 15a (second side wall 15 b) based on the vertical line may be not less than 85° and not more than 95°. Preferably, the inclination angle of the first side wall 15a (second side wall 15b) is not less than 87° and not more than 93°. The bottom wall 15 c is formed by a c-plane (Si plane) of the SiC monocrystal. Preferably, the bottom wall 15c extends substantially flatly along the horizontal direction. As a matter of course, the bottom wall 15c may be curved in a circular arc shape toward the second principal surface 4 side.

The gate structure 15 may have a width of not less than 0.1 μm and not more than 1.5 μm. The width of the gate structure 15 may have a value falling within at least one range among not less than 0.1 μm and not more than 0.25 μm, not less than 0.25 μm and not more than 0.5 μm, not less than 0.5 μm and not more than 0.75 μm, not less than 0.75 μm and not more than 1 μm, not less than 1 μm and not more than 1.25 μm, and not less than 1.25 μm and not more than 1.5 μm. Preferably, the width of the gate structure 15 is not less than 0.25 μm and not more than 0.75 μm.

The gate structure 15 may have a depth of not less than 0.1 μm and not more than 3 μm. The depth of the gate structure 15 may have a value falling within at least one range among not less than 0.1 μm and not more than 0.5 μm, not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm. Preferably, the depth of the gate structure 15 is not less than 0.5 μm and not more than 1.5 μm. Preferably, the depth of the gate structure 15 is substantially equal to the depth of the second surface portion 9.

Each of the plurality of gate structures 15 includes a trench 16, an insulating film 17, and an embedded electrode 18. The trench 16 is formed in the first principal surface 3 (first surface portion 8), and demarcates a wall surface of the gate structure 15 (first side wall 15a, second side wall 15b, and bottom wall 15c). The trench 16 extends along the second direction Y. The depth direction of the trench 16 is the second direction Y. The depth direction of the gate structure 15 coincides with the depth direction of the trench 16, and is the second direction Y.

The insulating film 17 may include at least one among a silicon oxide film, a silicon nitride film, and a silicon oxynitride film. The insulating film 17 has a single layer structure consisting of a silicon oxide film in this preferred embodiment. Particularly preferably, the insulating film 17 includes a silicon oxide film constituted of an oxide of the chip 2.

The insulating film 17 covers a wall surface of the trench 16 in a film shape. The insulating film 17 includes a first film portion, a second film portion, and a third film portion. The first film portion covers the first side wall 15a in a film shape. The second film portion covers the second side wall 15b in a film shape. The third film portion covers the bottom wall 15c in a film shape, and is continuous with the first film portion and with the second film portion. The second film portion has a thickness substantially equal to the thickness of the first film portion. The third film portion has a thickness larger than both the thickness of the first film portion and the thickness of the second film portion. As a matter of course, the thickness of the third film portion may be substantially equal to the thickness of the first film portion and to the thickness of the second film portion. The insulating film 17 may have a thickness of not less than 10 nm and not more than 150 nm.

The embedded electrode 18 may include either one or both of p-type conductive polysilicon and n-type conductive polysilicon. The embedded electrode 18 is embedded in the trench 16 across the insulating film 17. The embedded electrode 18 has an electrode surface exposed from the trench 16. The electrode surface is placed on the bottom wall 15c side with respect to a height position of the first principal surface 3. The electrode surface has a recess that is recessed in a shape tapering toward the bottom wall 15c side in an inner portion. Preferably, a bottom portion of the recess is placed on the first principal surface 3 side with respect to a depth position of an intermediate portion of the trench 16.

Referring to FIG. 5 and FIG. 6, the semiconductor device 1 includes a plurality of p-type body regions 20 formed at the surface layer portion of the first principal surface 3 (first surface portion 8). A source potential is applied as a second potential (low potential) differing from the first potential (high potential) to the plurality of body regions 20. The body region 20 may be referred to as a “channel region,” a “base region,” etc. The plurality of body regions 20 may have a p-type impurity concentration of not less than 1×10¹⁷ cm⁻³ and not more than 1×10¹⁹ cm⁻³.

The plurality of body regions 20 are respectively formed in regions along the plurality of gate structures 15. In detail, the plurality of body regions 20 are each formed in a region between the plurality of gate structures 15, and each extend in a band shape along the plurality of gate structures 15.

Referring to FIG. 6 and FIG. 9, a configuration of the single body region 20 will be hereinafter described. In this preferred embodiment, the body region 20 is formed in a layer shape extending in the first direction X in a cross-sectional view, and is connected to either one or both (in this preferred embodiment, both) of the plurality of gate structures 15 adjacent each other. The body region 20 faces the embedded electrodes 18 of the plurality of gate structures 15 across the insulating films 17 of the plurality of gate structures 15.

The body region 20 is formed at an interval from a depth position of the second surface portion 9 in a region on the first surface portion 8 side. The body region 20 is formed at an interval from a depth position of the bottom wall 15c of the gate structure 15 toward the first principal surface 3 side. The body region 20 has a bottom portion placed on the bottom wall 15c side (see FIG. 9) of the gate structure 15 with respect to a depth position of an intermediate portion of the gate structure 15.

The bottom portion of the body region 20 is placed in a region between the bottom wall 15c of the gate structure 15 and the intermediate portion of the gate structure 15. A distance between the bottom portion of the body region 20 and the bottom wall 15c of the gate structure 15 is less than a thickness (depth) T_{B} of the body region 20 (see FIG. 9). The bottom portion of the body region 20 is placed on the bottom wall 15c side of the gate structure 15 with respect to the bottom portion of the recess of the embedded electrode 18. As a matter of course, the bottom portion of the body region 20 may be placed on the first principal surface 3 side with respect to the depth position of the intermediate portion of the gate structure 15.

The body region 20 may have a thickness of not less than 0.1 μm and not more than 1 μm. The thickness T_{B} of the body region 20 (see FIG. 9) may have a value falling within at least one range among not less than 0.1 μm and not more than 0.2 μm, not less than 0.2 μm and not more than 0.4 μm, not less than 0.4 μm and not more than 0.6 μm, not less than 0.6 μm and not more than 0.8 μm, and not less than 0.8 μm and not more than 1 μm. Preferably, the thickness T_{B} of the body region 20 (see FIG. 9) is not less than 0.3 μm and not more than 0.7 μm.

Referring to FIG. 4, FIG. 6, and FIG. 9, the semiconductor device 1 includes a plurality of n-type source regions 21 formed in a region on the first principal surface 3 side with respect to the plurality of body regions 20. The plurality of source regions 21 have an n-type impurity concentration higher than the n-type impurity concentration of the second semiconductor region 7. The n-type impurity concentration of the plurality of source regions 21 may be not less than 1×10¹⁸ cm⁻³ and not more than 1×10²¹ cm⁻³.

The plurality of source regions 21 are respectively formed in regions along the plurality of gate structures 15 in the surface layer portions of the plurality of body regions 20. In detail, the plurality of source regions 21 are each formed in a region between the plurality of gate structures 15, and each extend in a band shape along the plurality of gate structures 15.

Referring to FIG. 6 and FIG. 9, a configuration of the single source region 21 will be hereinafter described. The source region 21 is formed at an interval from the bottom portion of the body region 20 toward the first principal surface 3 side. In this preferred embodiment, the source region 21 is formed in a layer shape extending in the first direction X in the cross-sectional view, and is connected to either one or both (in this preferred embodiment, both) of the plurality of gate structures 15 adjacent each other. The source region 21 faces the embedded electrodes 18 of the plurality of gate structures 15 across the insulating films 17 of the plurality of gate structures 15.

The source region 21 has a bottom portion placed on the bottom wall 15c side (see FIG. 9) of the trench 16 with respect to a height position of the electrode surface of the embedded electrode 18, and a surface layer portion placed on the first principal surface 3 side with respect to the height position of the electrode surface of the embedded electrode 18. The source region 21 has a portion (bottom portion) that faces the embedded electrode 18 across the insulating film 17 and a portion (surface layer portion) that does not face the embedded electrode 18 across the insulating film 17.

The bottom portion of the source region 21 may be placed on the first principal surface 3 side with respect to a depth position of the bottom portion of the recess of the embedded electrode 18. As a matter of course, the bottom portion of the source region 21 may be placed on the bottom portion side of the body region 20 with respect to the depth position of the bottom portion of the recess.

The semiconductor device 1 includes a plurality of p-type well regions 22 formed in the chip 2 (second semiconductor region 7). The plurality of well regions 22 have a p-type impurity concentration higher than the p-type impurity concentration of the body region 20. As a matter of course, the p-type impurity concentration of the plurality of well regions 22 may be equal to the p-type impurity concentration of the body region 20, or may be less than the p-type impurity concentration of the body region 20. The p-type impurity concentration of the plurality of well regions 22 may be not less than 1×10¹⁶ cm⁻³ and not more than 1×10²⁰ cm⁻³. The plurality of well regions 22 may be referred to as a “field relaxation layer.”

The plurality of well regions 22 are respectively formed at an interval from each other in the first direction X in regions along the bottom walls 15c of the plurality of gate structures 15 in the chip 2 (second semiconductor region 7). The plurality of well regions 22 are each formed in a one-to-one correspondence with the plurality of gate structures 15 in this preferred embodiment.

The plurality of well regions 22 are each formed in a band shape extending along corresponding one of the gate structures 15 in the plan view, and face corresponding one of the embedded electrodes 18 across corresponding one of the insulating films 17. As a matter of course, the plurality of well regions 22 may be formed in a multiple-to-one correspondence relationship with respect to the single gate structure 15. In this case, the plurality of well regions 22 are formed at an interval from each other in the second direction Y.

Referring to FIG. 5, FIG. 6, etc., a configuration of the single well region 22 will be hereinafter described. The well region 22 is formed more widely than the gate structure 15 in the plan view. The well region 22 is formed in a pillar shape extending in the thickness direction (vertical direction Z) of the second semiconductor region 7 in the cross-sectional view

The well region 22 may have a depth crossing an intermediate portion between the bottom portion of the second semiconductor region 7 and the bottom wall 15c of the gate structure 15. The well region 22 may be formed at an interval from the intermediate portion between the bottom portion of the second semiconductor region 7 and the bottom wall 15c of the gate structure 15 toward the first principal surface 3 side.

The well region 22 is formed at an interval from the bottom portion of the second semiconductor region 7 toward the first surface portion 8 side, and faces the first semiconductor region 6 across a portion of the second semiconductor region 7. As a matter of course, the well region 22 may cross the bottom portion of the second semiconductor region 7, and may have a bottom portion placed in the first semiconductor region 6. The well region 22 forms a pn junction portion with the second semiconductor region 7.

The well region 22 has a thickness (depth) larger than the thickness (depth) T_{B} of the body region 20 (see FIG. 9) in this preferred embodiment. The thickness of the well region 22 is a thickness in the vertical direction Z of the well region 22 based on the bottom wall 15c of the gate structure 15. The thickness of the well region 22 is larger than the depth of the gate structure 15 in this preferred embodiment. As a matter of course, the thickness of the well region 22 may be less than the depth of the gate structure 15. In this case, the thickness of the well region 22 may be less than the thickness T_{B} of the body region 20 (see FIG. 9).

The well region 22 has an upper end portion along a corner portion of the bottom wall 15c of the gate structure 15. The well region 22 has a first extension portion 22a on the first side wall 15a side and a second extension portion 22b on the second side wall 15b side (see FIG. 9) in the upper end portion.

The first extension portion 22a is led out from a region directly below the gate structure 15 to a lower end portion of the first side wall 15a. The first extension portion 22a is formed at an interval from the bottom portion of the body region 20 toward the bottom wall 15c side of the gate structure 15. The first extension portion 22a faces the embedded electrode 18 in the horizontal direction across the insulating film 17 in this preferred embodiment.

As a matter of course, the first extension portion 22a may be formed on the bottom wall 15c side of the trench 16 with respect to a depth position of a lower end portion of the embedded electrode 18, and may face only the insulating film 17 (third film portion) in the horizontal direction. The first extension portion 22a is formed in a tapered shape toward the first principal surface 3 (bottom portion side of the body region 20) in the cross-sectional view.

The second extension portion 22b is led out from the region directly below the gate structure 15 to a lower end portion of the second side wall 15b, and faces the first extension portion 22a across the gate structure 15. The second extension portion 22b is formed at an interval from the bottom portion of the body region 20 toward the bottom wall 15c side of the gate structure 15. The second extension portion 22b faces the embedded electrode 18 in the horizontal direction across the insulating film 17 in this preferred embodiment.

As a matter of course, the second extension portion 22b may be formed on the bottom wall 15c side of the trench 16 with respect to the depth position of the lower end portion of the embedded electrode 18, and may face only the insulating film 17 (third film portion) in the horizontal direction. The second extension portion 22b is formed in a tapered shape toward the first principal surface 3 (bottom portion side of the body region 20) in the cross-sectional view.

The well region 22 has one or a plurality of (in this preferred embodiment, a plurality of) first bulging portions 22c (see FIG. 8). The well region 22 having four first bulging portions 22c is shown in FIG. 8 as an example. The number of the first bulging portions 22c is appropriately adjusted by adjusting process conditions. The plurality of first bulging portions 22c are each formed by a portion in which the width in the horizontal direction (first direction X) of the well region 22 is gradually increased or decreased in the thickness direction, and are formed in a multi-step manner from the bottom wall 15c of the gate structure 15 toward the bottom portion of the second semiconductor region 7.

The plurality of first bulging portions 22c bulge from the region directly below the gate structure 15 toward both sides of the gate structure 15 in an arc shape (circular arc shape). When the well region 22 has the single first bulging portion 22c, the single first bulging portion 22c may be formed such as to protrude to both sides of the gate structure 15 in an arc shape (circular arc shape) in an intermediate portion of the well region 22.

The semiconductor device 1 includes a plurality of high-concentration p-type well regions 23 respectively formed in the plurality of well regions 22. The plurality of high-concentration well regions 23 are regions in which the p-type impurity concentration of the well region 22 has been increased, and have a p-type impurity concentration higher than the p-type impurity concentration of the well region 22. The high-concentration well region 23 is regarded as a portion of the well region 22 in this preferred embodiment. In this case, the high-concentration well region 23 is regarded as a high-concentration portion of the well region 22. The p-type impurity concentration of the plurality of high-concentration well regions 23 may be not less than 1×10¹⁸ cm⁻³ and not more than 1×10²⁰ cm⁻³. The plurality of high-concentration well regions 23 may be referred to as “high-concentration field relaxation layers.”

The plurality of high-concentration well regions 23 are each formed in a one-to-one correspondence with the plurality of well regions 22. The plurality of high-concentration well regions 23 are each formed in a region along the bottom wall 15c of corresponding one of the gate structures 15. The plurality of high-concentration well regions 23 are each formed in a band shape extending along corresponding one of the gate structures 15 (well region 22) in the plan view, and face corresponding one of the embedded electrodes 18 across corresponding one of the insulating films 17.

Referring to FIG. 5, FIG. 6, etc., a configuration of the single high-concentration well region 23 will be hereinafter described. The high-concentration well region 23 is formed at an interval from the bottom portion of the well region 22 toward the bottom wall 15c side of the gate structure 15. Preferably, the high-concentration well region 23 has a bottom portion 23a (see FIG. 8 and FIG. 9) placed on the bottom wall 15c side of the gate structure 15 with respect to a depth position of the intermediate portion of the well region 22.

The bottom portion 23a of the high-concentration well region 23 is a concentration transition portion in which the p-type impurity concentration gradually decreases toward the bottom portion side of the well region 22. As a matter of course, the bottom portion 23a of the high-concentration well region 23 may be placed on the bottom portion side of the well region 22 with respect to the depth position of the intermediate portion of the well region 22.

The high-concentration well region 23 is formed such as to be narrower in width than the well region 22. The high-concentration well region 23 is formed such as to be narrower in width than the gate structure 15 in this preferred embodiment. As a matter of course, the high-concentration well region 23 may be formed more widely than the gate structure 15, and may bulge laterally from both sides from the gate structure 15.

The high-concentration well region 23 has a thickness (depth) T_{H} less than the depth of the gate structure 15 (see FIG. 8 and FIG. 9). The thickness T_{H} of the high-concentration well region 23 is the thickness in the vertical direction Z of the high-concentration well region 23 based on the bottom wall 15c of the gate structure 15. The thickness of the high-concentration well region 23 is less than the thickness of the body region 20. As a matter of course, the thickness of the high-concentration well region 23 may be larger than the thickness of the body region 20, and may be larger than the depth of the gate structure 15.

The semiconductor device 1 includes a plurality of n-type high-concentration regions 24 that are respectively formed in regions below the plurality of body regions 20 in the chip 2 (second semiconductor region 7). The plurality of high-concentration regions 24 are regions in which the n-type impurity concentration of the second semiconductor region 7 has been increased, and have an n-type impurity concentration higher than the n-type impurity concentration of the second semiconductor region 7. The plurality of high-concentration regions 24 may be each regarded as a high-concentration portion of the second semiconductor region 7.

The n-type impurity concentration of the plurality of high-concentration regions 24 may be not less than 1×10¹⁶ cm⁻³ and not more than 1×10¹⁹ cm⁻³. For example, the n-type impurity concentration of the plurality of high-concentration regions 24 can be appropriately compared by being compared with the n-type impurity concentration on the bottom portion side of the second semiconductor region 7.

The plurality of high-concentration regions 24 are respectively formed in regions along the plurality of gate structures 15 in the regions below the plurality of body regions 20. In detail, the plurality of high-concentration regions 24 are each formed within a thickness range between the bottom wall 15c of the plurality of gate structures 15 and the bottom portion of the plurality of body regions 20 in a region between the plurality of gate structures 15. Each of the plurality of high-concentration regions 24 extends in a band shape along the plurality of gate structures 15 in the plan view.

Referring to FIG. 5 and FIG. 6, a configuration of the single high-concentration region 24 will be hereinafter described. In this preferred embodiment, the high-concentration region 24 is formed in a layer shape extending in the first direction X in the cross-sectional view, and is connected to either one or both (in this preferred embodiment, both) of the plurality of gate structures 15 adjacent each other. The high-concentration region 24 faces the embedded electrodes 18 of the plurality of gate structures 15 across the insulating films 17 of the plurality of gate structures 15.

The high-concentration region 24 faces the source region 21 across a portion of the body region 20 with respect to the thickness direction. The high-concentration region 24 faces the source region 21 in the thickness direction in a one-to-one correspondence in this preferred embodiment. The high-concentration region 24 is formed at an interval from the bottom portion of the second semiconductor region 7 toward the first principal surface 3 side, and faces the first semiconductor region 6 across a portion of the second semiconductor region 7.

The plurality of high-concentration regions 24 may have an n-type impurity concentration that is substantially equal to each other, or may have an n-type impurity concentration that is different from each other.

The semiconductor device 1 includes a plurality of n-type intermediate-concentration regions (drift regions) 25 that are respectively formed in regions below the plurality of high-concentration regions 24 in the chip 2 (second semiconductor region 7). The plurality of intermediate-concentration regions 25 are regions in which the n-type impurity concentration of the second semiconductor region 7 has been increased, and have an n-type impurity concentration higher than the n-type impurity concentration of the second semiconductor region 7 and lower than the n-type impurity concentration of the high-concentration region 24. The plurality of intermediate-concentration regions 25 may be regarded as high-concentration portions of the second semiconductor region 7.

The n-type impurity concentration of the plurality of intermediate-concentration regions 25 may be not less than 1×10¹⁵ cm⁻³ and not more than 1×10¹⁷ cm⁻³. For example, the n-type impurity concentration of the plurality of intermediate-concentration regions 25 can be appropriately compared by being compared with the n-type impurity concentration on the bottom portion side of the second semiconductor region 7. The intermediate-concentration region 25 may be referred to as an “intermediate-concentration drift region.”

The plurality of intermediate-concentration regions 25 are respectively formed within a thickness range between the bottom portion of the second semiconductor region 7 and the bottom portion of the high-concentration regions 24 in a region between the plurality of gate structures 15. Each of the plurality of intermediate-concentration regions 25 has a portion interposed in a region between the plurality of well regions 22. Each of the plurality of intermediate-concentration regions 25 has a portion interposed in the region of the plurality of gate structures 15 in this preferred embodiment.

Each of the plurality of intermediate-concentration regions 25 extends in a band shape along the plurality of gate structures 15 in the plan view. In this preferred embodiment, the plurality of intermediate-concentration regions 25 are connected to either one or both (in this preferred embodiment, both) of the well regions 22 with respect to the two well regions 22 adjacent each other.

Referring to FIG. 5 and FIG. 6, a configuration of the single intermediate-concentration region 25 will be hereinafter described. The intermediate-concentration region 25 is formed at an interval from the bottom portion of the second semiconductor region 7 toward the first principal surface 3 side, and faces the first semiconductor region 6 across a portion of the second semiconductor region 7.

The intermediate-concentration region 25 has an upper end portion placed at an upper position with respect to the depth position of the bottom wall 15c of the gate structure 15. The upper end portion of the intermediate-concentration region 25 is placed in a region between the plurality of gate structures 15, and faces the gate structure 15 across the upper end portion (first extension portion 22a and second extension portion 22b) of the well region 22. The upper end portion of the intermediate-concentration region 25 may have a portion connected to the gate structure 15.

The intermediate-concentration region 25 has a bottom portion placed at a lower position with respect to the depth position of the bottom wall 15c of the gate structure 15. In detail, the bottom portion of the intermediate-concentration region 25 is formed at an interval from the bottom portion of the well region 22 toward the first principal surface 3 side. Preferably, the bottom portion of the intermediate-concentration region 25 is placed closer to the bottom portion of the well region 22 than to the bottom portion of the high-concentration well region 23.

The semiconductor device 1 includes a plurality of channel regions 26 (see FIG. 9) that are respectively formed between the plurality of source regions 21 and the plurality of high-concentration regions 24 in the plurality of body regions 20. The inversion and the non-inversion of the plurality of channel regions 26 are controlled by the gate structure 15. The plurality of channel regions 26 form current paths that connect the plurality of source regions 21 and the plurality of high-concentration regions 24 along the side walls (first side wall 15a and second side wall 15b) of the plurality of gate structures 15 in the plurality of body regions 20, respectively.

Referring to FIG. 4, FIG. 5, and FIG. 8, the semiconductor device 1 includes a plurality of p-type first contact regions 27 that are respectively formed in regions along the plurality of gate structures 15 in the surface layer portion of the first principal surface 3 (first surface portion 8). The plurality of first contact regions 27 have a p-type impurity concentration higher than the p-type impurity concentration of the plurality of body regions 20. The p-type impurity concentration of the plurality of first contact regions 27 is higher than the p-type impurity concentration of the plurality of well regions 22. The p-type impurity concentration of the plurality of first contact regions 27 may be not less than 1×10¹⁷ cm⁻³ and not more than 1×10¹⁹ cm⁻³.

The plurality of first contact regions 27 are each formed in a region between the plurality of gate structures 15. The plurality of first contact regions 27 are each formed at both sides of the plurality of gate structures 15. The plurality of first contact regions 27 are arrayed at an interval in the second direction Y along the plurality of gate structures 15, and are each formed in a band shape extending in the second direction Y. The plurality of first contact regions 27 are overlapped at the plurality of body regions 20, and increase the p-type impurity concentration of the plurality of body regions 20.

With respect to one of and the other one of the first contact regions 27 placed at both sides of the single gate structure 15, the other one of the first contact regions 27 faces the one of the first contact regions 27, across the gate structure 15. The plurality of first contact regions 27 are arrayed in a matrix manner as a whole in the plan view.

With respect to the second direction Y, the length and the interval of the plurality of first contact regions 27 are appropriately adjusted in accordance with a channel area to be achieved. The channel area corresponds to the total area of the plurality of source regions 21. The length in the second direction Y of the first contact region 27 may be larger than the width in the first direction X of the gate structure 15. As a matter of course, the length of the first contact region 27 may be less than the width of the gate structure 15. The length ratio of the length of the first contact region 27 with respect to the width of the gate structure 15 may be not less than 0.5 and not more than 10. The length ratio of the interval of the first contact region 27 with respect to the length of the first contact region 27 may be not less than 1 and not more than 50.

Referring to FIG. 5 and FIG. 8, a configuration of the single first contact region 27 will be hereinafter described. The first contact region 27 is formed in a layer shape extending in the horizontal direction along the first principal surface 3, and is connected to either one or both (in this preferred embodiment, both) of the plurality of gate structures 15 adjacent each other. The first contact region 27 faces the embedded electrodes 18 of the plurality of gate structures 15 across the insulating films 17 of the plurality of gate structures 15.

The first contact region 27 has a thickness larger than the thickness of the source region 21, and has a bottom portion placed closer to the bottom portion of the second semiconductor region 7 than to the bottom portion of the source region 21. The bottom portion of the first contact region 27 is placed on the bottom portion side of the body region 20 with respect to the depth position of the bottom portion of the recess of the embedded electrode 18.

In this preferred embodiment, the first contact region 27 has a thickness larger than the thickness T_{B} of the body region 20 (see FIG. 9), and has a bottom portion placed closer to the bottom portion of the second semiconductor region 7 than to the bottom portion of the body region 20. The bottom portion of the first contact region 27 is a concentration transition portion in which the p-type impurity concentration gradually decreases toward the bottom portion side of the second semiconductor region 7.

The bottom portion of the first contact region 27 may be placed closer to the first principal surface 3 than to the depth position of the bottom wall 15c of the gate structure 15 (see FIG. 8). In this case, the first contact region 27 may have a thickness less than the thickness of the body region 20, and may have a bottom portion placed closer to the first principal surface 3 side than to the bottom portion of the body region 20. The first contact region 27 may face the high-concentration region 24 across a portion of the body region 20.

The bottom portion of the first contact region 27 is placed closer to the bottom portion of the second semiconductor region 7 than to the depth position of the bottom wall 15c of the gate structure 15 (see FIG. 8) in this preferred embodiment. In this preferred embodiment, the first contact region 27 is overlapped with a portion or all of the high-concentration region 24 in the cross-sectional view. The first contact region 27 replaces the n-type impurity concentration of a portion or all of the high-concentration region 24 with the p-type impurity concentration. Therefore, the p-type impurity concentration of the bottom portion of the first contact region 27 is decreased in proportion to the n-type impurity concentration of the high-concentration region 24.

The first contact region 27 has a bottom portion that crosses the bottom portion of the high-concentration region 24 and that is placed in the intermediate-concentration region 25 in this preferred embodiment. Therefore, the first contact region 27 also replaces the n-type impurity concentration of a portion of the intermediate-concentration region 25 with the p-type impurity concentration. Preferably, the bottom portion of the first contact region 27 is placed closer to the first principal surface 3 than to the depth position of the intermediate portion of the well region 22.

The bottom portion of the first contact region 27 is overlapped with the upper end portion of the well region 22 in a region closer to the bottom portion of the second semiconductor region 7 than to the depth position of the bottom wall 15c of the gate structure 15. Thus, the first contact region 27 electrically connects the well region 22 to the body region 20.

Referring to FIG. 8, the first contact region 27 has a high-concentration portion 27a on the first principal surface 3 side and a low-concentration portion 27b on the bottom portion side of the second semiconductor region 7 in this preferred embodiment. The high-concentration portion 27a is formed closer to the first principal surface 3 than to at least the depth position of the bottom wall 15c of the gate structure 15, and forms a main body portion of the first contact region 27. The high-concentration portion 27a extends in a layer shape in the horizontal direction along the first principal surface 3.

The low-concentration portion 27b is formed on the bottom portion side of the second semiconductor region 7 with respect to the high-concentration portion 27a, and forms the bottom portion of the first contact region 27. The low-concentration portion 27b is also a portion in which the p-type impurity concentration is decreased by the n-type impurity concentration of the high-concentration region 24. The low-concentration portion 27b has a thickness less than the thickness of the high-concentration portion 27a, and extends in a layer shape in the horizontal direction along the high-concentration portion 27a.

The low-concentration portion 27b crosses the depth position of the bottom wall 15c of the gate structure 15 in the thickness direction. The low-concentration portion 27b has a portion placed closer to the first principal surface 3 than to the depth position of the bottom wall 15c of the gate structure 15 and a portion placed closer to the bottom portion of the second semiconductor region 7 than to the depth position of the bottom wall 15c of the gate structure 15. The low-concentration portion 27b is overlapped with the upper end portions of the plurality of well regions 22, and is electrically connected to the plurality of well regions 22.

Referring to FIG. 7, the gate structure 15 includes a first portion 15P sandwiched between the first contact regions 27 in the first direction X in the plan view and a second portion 15Q sandwiched between the source regions 21 in the first direction X in the plan view. The first portion 15P and the second portion 15Q are alternately formed in the second direction Y. The first portion 15P and the second portion 15Q adjacent each other are continuous with each other.

In the first portion 15P of the gate structure 15, a channel region is not formed at the side wall of the gate structure 15 (first side wall 15a and second side wall 15b) as shown in FIG. 8. On the other hand, in the second portion 15Q of the gate structure 15, the channel region 26 is formed at the side wall of the gate structure 15 (first side wall 15a and second side wall 15b) as shown in FIG. 9. The first portion 15P of the gate structure 15 is a portion in which the channel region 26 is not formed, and the second portion 15Q of the gate structure 15 is a portion in which the channel region 26 is formed.

Referring to FIG. 7 and FIG. 8, in the intermediate-concentration region 25 and in the second semiconductor region 7, a first lower region (non-channel lower region) 61 is formed below the first portion 15P of the gate structure 15 (portion in which the channel region 26 is not formed). A second contact region 28 is formed in the first lower region 61 in this preferred embodiment. The well region 22 is formed in the first lower region 61.

Referring to FIG. 7 and FIG. 9, in the intermediate-concentration region 25 and in the second semiconductor region 7, a second lower region (channel lower region) 62 is formed below the second portion 15Q of the gate structure 15 (portion in which the channel region 26 is formed). The second contact region 28 is not formed in the second lower region 62 in this preferred embodiment. The depth of the well region 22 of the second lower region 62 is shallower than the depth of the well region 22 of the first lower region 61.

Referring to FIG. 7 to FIG. 9, the well region 22 includes a first well region 51 and a second well region 53 that differ from each other in the depth position of the bottom portion. The first well region 51 and the second well region 53 are alternately formed in the second direction Y. The first well region 51 and the second well region 53 adjacent each other in the second direction Y are continuous with each other.

The first well region 51 has a first bottom portion 52. The first bottom portion 52 is placed in the second semiconductor region 7 penetrating through the intermediate-concentration region 25. The first bottom portion 52 is placed at a lower position with respect to the bottom portion 23a of the high-concentration well region 23. The first bottom portion 52 is placed at a lower position with respect to a bottom portion 28d of the second contact region 28.

The first bottom portion 52 has a first depth D₁ (see FIG. 8). The first depth D₁ is the depth of the first bottom portion 52 of the first well region 51 based on the bottom wall 15c of the gate structure 15. The first depth D₁ (see FIG. 8) is larger than the thickness T_{B} of the body region 20 (see FIG. 9) (D₁>T_{B}).

Referring to FIG. 7 and FIG. 8, the first well region 51 is formed in the first lower region 61 below the second portion 15Q of the gate structure 15. In detail, the first well region 51 is formed in the whole area in the second direction Y in the first lower region 61. In this preferred embodiment, the second well region 53 is not formed in the first lower region 61.

Referring to FIG. 7, the first well region 51 is formed at a distance of a first interval W₁ from the adjacent first well region 51. The first interval W₁ may be equal to the length in the second direction Y of the first contact region 27. The first interval W₁ may be larger than the width in the first direction X of the gate structure 15. As a matter of course, the first interval W₁ may be less than the length of the first contact region 27 and the width of the gate structure 15. The length ratio of the first interval W₁ with respect to the width in the first direction X of the gate structure 15 may be not less than 0.5 and not more than 10.

Referring to FIG. 8, the first well region 51 has one or a plurality of (in this preferred embodiment, a plurality of) first bulging portions 22c. In the example of FIG. 8, the first well region 51 includes neither the first extension portion 22a (see FIG. 9) nor the second extension portion 22b (see FIG. 9). As a matter of course, the first well region 51 may include the first extension portion 22a and the second extension portion 22b.

Referring to FIG. 7 and FIG. 9, the second well region 53 has a second bottom portion 54. The second well region 53 has a second depth D₂ (see FIG. 9). The second bottom portion 54 is placed in the intermediate-concentration region 25. The second bottom portion 54 is placed at a lower position with respect to the bottom portion 23a of the high-concentration well region 23. The second depth D₂ (see FIG. 9) is smaller than the thickness T_{B} of the body region 20 (see FIG. 9) (D₂<T_{B}). As a matter of course, the second depth D₂ may be equal to or more than the thickness T_{B} of the body region 20 (D₂≥T_{B}).

The second bottom portion 54 of the second well region 53 is placed on the first principal surface 3 side with respect to the bottom portion 28d of the second contact region 28. The second bottom portion 54 of the second well region 53 is placed on the first principal surface 3 side with respect to the depth position of the intermediate portion of the intermediate-concentration region 25. As a matter of course, the second bottom portion 54 of the second well region 53 may be placed on the second principal surface 4 side with respect to the depth position of the intermediate portion of the intermediate-concentration region 25.

The second bottom portion 54 of the second well region 53 is placed closer to the second principal surface 4 than to the bottom portion 23a of the high-concentration well region 23. The bottom portion 23a of the high-concentration well region 23 is placed closer to the bottom wall 15c of the gate structure 15 than to the second bottom portion 54 of the second well region 53. A second interval W₂ in the thickness direction between the second bottom portion 54 of the second well region 53 and the bottom portion 23a of the high-concentration well region 23 is smaller than the thickness T_{H} of the high-concentration well region 23. As a matter of course, the second interval W₂ may be equal to or more than the thickness T_{H} of the high-concentration well region 23.

Referring to FIG. 7 and FIG. 9, the second well region 53 is formed in the second lower region 62 below the second portion 15Q of the gate structure 15. In detail, the second well region 53 is formed in the whole area in the second direction Y in the second lower region 62. The first well region 51 is not formed in the second lower region 62.

Referring to FIG. 7, the intermediate-concentration region 25 and the second semiconductor region 7 include a sandwiched portion (partial) 7a sandwiched between the first well regions 51 adjacent each other in the second direction Y. The first well regions 51 adjacent each other in the second direction Y face each other across the sandwiched portion 7a in the second direction Y. The plurality of sandwiched portions 7a are formed at an interval from each other in the second direction Y. The length in the second direction Y of the sandwiched portion 7a coincides with the first interval W₁ between the first well regions 51 adjacent each other. The sandwiched portion 7a has a flat upper surface.

The semiconductor device 1 includes a plurality of p-type second contact regions 28 that are respectively formed in regions along the bottom walls 15c of the plurality of gate structures 15 in the chip 2. The plurality of second contact regions 28 have a p-type impurity concentration higher than the p-type impurity concentration of the plurality of body regions 20. The p-type impurity concentration of the plurality of second contact regions 28 is higher than the p-type impurity concentration of the plurality of well regions 22. In this preferred embodiment, the second contact region 28 is included in the first well region 51, and is not included in the second well region 53.

The p-type impurity concentration of the plurality of second contact regions 28 may be not less than 1×10¹⁸ cm⁻³ and not more than 1×10²⁰ cm⁻³. Preferably, the p-type impurity concentration of the plurality of second contact regions 28 is substantially equal to the p-type impurity concentration of the plurality of first contact regions 27.

The plurality of second contact regions 28 are respectively formed in a multiple-to-one correspondence relationship with respect to the bottom wall 15c of the plurality of gate structures 15. The plurality of second contact regions 28 are each interposed in a region between the first contact regions 27 adjacent each other in the first direction X in the plan view. The plurality of second contact regions 28 are placed on the same straight line as the plurality of first contact regions 27 in the first direction X.

The plurality of second contact regions 28 are each formed in a band shape extending along corresponding one of the gate structures 15 in the plan view, and face the embedded electrode 18 across the insulating film 17. With respect to the second direction Y, the length of the plurality of second contact regions 28 is substantially equal to the length of the plurality of first contact regions 27. With respect to the second direction Y, the interval between the plurality of second contact regions 28 is substantially equal to the interval between the plurality of first contact regions 27.

Referring to FIG. 5 and FIG. 8, a configuration of the single second contact region 28 will be hereinafter described. The second contact region 28 is formed in corresponding one of the well regions 22 (first well regions 51). The high-concentration well region 23 is overlapped with the second contact region 28, and is electrically connected to the high-concentration well region 23 in the well region 22. The second contact region 28 is formed at an interval inward from the peripheral edge portion of the well region 22. The second contact region 28 has the bottom portion 28d.

Referring to FIG. 8, the second contact region 28 is formed at an interval from the bottom portion of the well region 22 toward the bottom wall 15c side of the gate structure 15, and faces the bottom portion of the second semiconductor region 7 across a portion of the well region 22. Each second contact region 28 is formed in a pillar shape extending in the thickness direction (in the vertical direction Z) of the second semiconductor region 7 in the cross-sectional view.

The second contact region 28 has a bottom portion placed closer to the bottom portion of the well region 22 than to the thickness position of the intermediate portion of the well region 22 in this preferred embodiment. As a matter of course, the bottom portion of the second contact region 28 may be placed closer to the bottom wall 15c of the gate structure 15 than to the thickness position of the intermediate portion of the well region 22.

The second contact region 28 has an upper end portion along the corner portion of the bottom wall 15c of the gate structure 15. The second contact region 28 is electrically connected to the plurality of first contact regions 27 in the upper end portion. The second contact region 28 electrically connects the well region 22 and the high-concentration well region 23 to the body region 20 through the plurality of first contact regions 27.

The second contact region 28 has a first extension portion 28a on the first side wall 15a side and a second extension portion 28b on the second side wall 15b side. The first extension portion 28a is led out from the region directly below the gate structure 15 to the lower end portion of the first side wall 15a. The first extension portion 28a faces the embedded electrode 18 across the insulating film 17 in the horizontal direction. The first extension portion 28a is connected to the first contact region 27 in a region along the first side wall 15a. In detail, the first extension portion 28a is connected to both the high-concentration portion 27a and the low-concentration portion 27b of the first contact region 27.

The second extension portion 28b is led out from the region directly below the gate structure 15 to the lower end portion of the second side wall 15b, and faces the first extension portion 28a across the gate structure 15. The second extension portion 28b faces the embedded electrode 18 across the insulating film 17 in the horizontal direction. The second extension portion 28b is connected to the first contact region 27 in a region along the second side wall 15b. In detail, the second extension portion 28b is connected to both the high-concentration portion 27a and the low-concentration portion 27b of the first contact region 27.

The second contact region 28 has one or a plurality of (in this preferred embodiment, a plurality of) second bulging portions 28c. In FIG. 8, the second contact region 28 having two second bulging portions 28c is shown as an example. The number of the second bulging portions 28c is appropriately adjusted by adjusting process conditions. The plurality of second bulging portions 28c are each formed by a portion in which the width in the horizontal direction (first direction X) of the second contact region 28 is gradually increased or decreased in the thickness direction, and are formed in a multi-step manner from the bottom wall 15c of the gate structure 15 toward the bottom portion of the second semiconductor region 7.

Referring to FIG. 2, the semiconductor device 1 includes a principal surface insulating film 30 covering the first principal surface 3. The principal surface insulating film 30 selectively covers the first surface portion 8, the second surface portion 9, and the first to fourth connecting surface portions 10A to 10D. The principal surface insulating film 30 is connected to the insulating films 17 of the plurality of gate structures 15 in the first surface portion 8, and exposes the embedded electrodes 18 of the plurality of gate structures 15.

The principal surface insulating film 30 may include at least one among a silicon oxide film, a silicon nitride film, and a silicon oxynitride film. The principal surface insulating film 30 has a single layer structure constituted of a silicon oxide film in this preferred embodiment. Particularly preferably, the principal surface insulating film 30 includes a silicon oxide film constituted of the oxide of the chip 2.

Referring to FIG. 2, the semiconductor device 1 includes an insulative interlayer film 31 covering the principal surface insulating film 30. The interlayer film 31 may be referred to as an “insulating film,” an “interlayer insulating film,” an “intermediate insulating film,” etc. The interlayer film 31 selectively covers the first surface portion 8, the second surface portion 9, and the first to fourth connecting surface portions 10A to 10D across the principal surface insulating film 30. The interlayer film 31 covers the plurality of gate structures 15 in the first surface portion 8.

The interlayer film 31 is continuous with the first to fourth side surfaces 5A to 5D in the peripheral edge portion of the second surface portion 9 in this preferred embodiment. As a matter of course, the interlayer film 31 may be formed at an interval inward from the peripheral edge of the second surface portion 9, and may expose the second semiconductor region 7 from the peripheral edge portion of the second surface portion 9. The interlayer film 31 may include at least one among a silicon oxide film, a silicon nitride film, and a silicon oxynitride film. Preferably, the interlayer film 31 includes a silicon oxide film.

The interlayer film 31 may have a thickness of not less than 0.5 μm and not more than 3 μm. The thickness of the interlayer film 31 may have a value falling within at least one range among not less than 0.5 μm and not more than 1 μm, not less than 1 μm and not more than 1.5 μm, not less than 1.5 μm and not more than 2 μm, not less than 2 μm and not more than 2.5 μm, and not less than 2.5 μm and not more than 3 μm.

Referring to FIG. 5 etc., the semiconductor device 1 includes a plurality of source openings 32 formed in the interlayer film 31. The plurality of source openings 32 are respectively formed in a region between the plurality of gate structures 15, and expose the plurality of source regions 21 and the plurality of first contact regions 27. The plurality of source openings 32 extend in a band shape in the second direction Y along the plurality of gate structures 15.

Preferably, each of the plurality of source openings 32 has an opening end curved in a circular arc shape. The plurality of source openings 32 may be formed at an interval from each other in the second direction Y in a region between the plurality of gate structures 15 adjacent each other. In this case, the plurality of source openings 32 may be formed in a quadrangular shape, a rectangular shape (band shape), a circular shape, etc., in the plan view.

Referring to FIG. 3, the semiconductor device 1 includes a plurality of gate openings 33 formed in the interlayer film 31. Each of the plurality of gate openings 33 selectively exposes both end portions of corresponding one of the gate structures 15 in this preferred embodiment. In detail, each of the plurality of gate openings 33 selectively exposes both end portions of the embedded electrode 18 of corresponding one of the gate structures 15. Preferably, each of the plurality of gate openings 33 has an opening end curved in a circular arc shape in the same way as the source opening 32. The plurality of gate openings 33 may be formed in a quadrangular shape, a rectangular shape (band shape), a circular shape, etc., in the plan view.

Referring to FIG. 1, FIG. 2, FIG. 5, etc., the semiconductor device 1 includes a source electrode 35 disposed on the first principal surface 3. The source electrode 35 is a terminal electrode to which a source potential is applied from the outside. The source electrode 35 is disposed on a portion of the interlayer film 31 that covers the first surface portion 8.

The source electrode 35 has a first pad portion 35a, a second pad portion 35b, and a third pad portion 35c in this preferred embodiment. The first pad portion 35a has a comparatively large plane area, and forms a main body of the source electrode 35. In this preferred embodiment, the first pad portion 35a is formed in a polygonal shape (in this preferred embodiment, quadrangular shape) having four sides parallel to the peripheral edges of the chip 2 in the plan view, and is shifted to the fourth side surface 5D side with respect to a central portion of the first surface portion 8.

The second pad portion 35b has a plane area less than the plane area of the first pad portion 35a, and is led out in a band shape (quadrangular shape) from one end portion (end portion on the first side surface 5A side) in the second direction Y of the first pad portion 35a toward the third side surface 5C. The third pad portion 35c has a plane area less than the plane area of the first pad portion 35a, and is led out in a band shape (quadrangular shape) from the other end portion (end portion on the second side surface 5B side) in the second direction Y of the first pad portion 35a toward the third side surface 5C, and faces the second pad portion 35b in the second direction Y.

The plane area of the third pad portion 35c may be substantially equal to the plane area of the second pad portion 35b. As a matter of course, the plane area of the third pad portion 35c may be larger than the plane area of the second pad portion 35b, and may be less than the plane area of the second pad portion 35b. Either one or both of the second pad portion 35b and the third pad portion 35c may be used as a terminal portion for current monitoring. The source electrode 35 may have only either one of the second pad portion 35b and the third pad portion 35c. As a matter of course, the source electrode 35 may consist only of the first pad portion 35a, and may have neither the second pad portion 35b nor the third pad portion 35c.

The source electrode 35 enters the plurality of source openings 32 from above the interlayer film 31, and is connected to the first principal surface 3 (first surface portion 8) in the plurality of source openings 32. The source electrode 35 is electrically connected to the plurality of source regions 21 and to the plurality of first contact regions 27 in the plurality of source openings 32.

Referring to FIG. 5 etc., the source electrode 35 has a laminated structure including a lower electrode film 36 and a principal electrode film 37 that are laminated in that order from the chip 2 side in this preferred embodiment. The lower electrode film 36 has a laminated structure including a first electrode film 38 and a second electrode film 39 in this preferred embodiment. The first electrode film 38 includes a Ti film, and the second electrode film 39 includes a TiN film in this preferred embodiment. The lower electrode film 36 is not necessarily required to have a laminated structure, and may have a single layer structure constituted of either one of the first electrode film 38 (Ti film) and the second electrode film 39 (TiN film). The first electrode film 38 has a thickness less than the thickness of the interlayer film 31. The thickness of the first electrode film 38 may be not less than 10 nm and not more than 100 nm. The second electrode film 39 has a thickness less than the thickness of the interlayer film 31. Preferably, the thickness of the second electrode film 39 is larger than the thickness of the first electrode film 38. The thickness of the second electrode film 39 may be not less than 50 nm and not more than 200 nm.

The first electrode film 38 collectively covers, in a film shape, a region of the interlayer film 31 in which the plurality of source openings 32 are formed, and enters the plurality of source openings 32 from above the interlayer film 31. The first electrode film 38 has a portion covering, in a film shape, an insulating principal surface of the interlayer film 31, a portion covering, in a film shape, the wall surfaces of the plurality of source openings 32, and a portion covering, in a film shape, the first principal surface 3 in the plurality of source openings 32. The first electrode film 38 covers, in a film shape, the first principal surface 3 (first surface portion 8) in the source opening 32, and is mechanically and electrically connected to the plurality of source regions 21 and to the plurality of first contact regions 27 on the first principal surface 3.

The second electrode film 39 directly covers the first electrode film 38. The second electrode film 39 collectively covers, in a film shape, the region of the interlayer film 31 in which the plurality of source openings 32 are formed across the first electrode film 38, and enters the plurality of source openings 32 from above the interlayer film 31. The second electrode film 39 has a portion covering, in a film shape, the insulating principal surface of the interlayer film 31 across the first electrode film 38, a portion covering, in a film shape, the wall surfaces of the plurality of source openings 32 across the first electrode film 38, and a portion covering, in a film shape, the first principal surface 3 across the first electrode film 38 in the plurality of source openings 32. The second electrode film 39 covers, in a film shape, the first principal surface 3 (first surface portion 8) across the first electrode film 38 in the source opening 32, and is electrically connected to the plurality of source regions 21 and to the plurality of first contact regions 27 through the first electrode film 38.

The principal electrode film 37 includes a conductive material differing from the lower electrode film 36 (first electrode film 38 and second electrode film 39). The principal electrode film 37 may include at least one among an Al film, an Al alloy film, a Cu film, and a Cu alloy film. The Al alloy film may include at least one among an AlSi alloy film, an AlCu alloy film, and an AlSiCu alloy film. The principal electrode film 37 has a thickness larger than the thickness (total thickness) of the lower electrode film 36. Preferably, the thickness of the principal electrode film 37 is larger than the thickness of the interlayer film 31. The thickness of the principal electrode film 37 may be not less than 0.5 μm and not more than 5 μm.

The principal electrode film 37 directly covers the lower electrode film 36 (second electrode film 39). The principal electrode film 37 backfills the plurality of source openings 32, and collectively covers, in a film shape, the region of the interlayer film 31 in which the plurality of source openings 32 are formed. The principal electrode film 37 has a portion covering the insulating principal surface of the interlayer film 31 across the lower electrode film 36, a portion covering the wall surfaces of the plurality of source openings 32 across the lower electrode film 36, and a portion covering the first principal surface 3 across the lower electrode film 36. The principal electrode film 37 covers the first principal surface 3 (first surface portion 8) across the lower electrode film 36 in the source opening 32, and is electrically connected to the plurality of source regions 21 and to the plurality of first contact regions 27 through the lower electrode film 36.

Referring to FIG. 1 and FIG. 2, the semiconductor device 1 includes a gate electrode 40 disposed on the first principal surface 3. The gate electrode 40 is a terminal electrode to which a gate potential is applied from the outside. The gate electrode 40 includes the lower electrode film 36 and the principal electrode film 37 that are laminated in that order from the chip 2 side in the same way as the source electrode 35, although not shown.

The gate electrode 40 is disposed at an interval from the source electrode 35 on a portion of the interlayer film 31 which covers the first surface portion 8. The gate electrode 40 is disposed in a region on the third side surface 5C side with respect to the first pad portion 35a, and faces the first pad portion 35a in the first direction X in this preferred embodiment. Additionally, the gate electrode 40 is interposed in a region between the second pad portion 35b and the third pad portion 35c, and faces both the second pad portion 35b and the third pad portion 35c in the second direction Y.

The gate electrode 40 is formed in a polygonal shape (in this preferred embodiment, quadrangular shape) having four sides parallel to the peripheral edges of the chip 2 in the plan view. The gate electrode 40 has a plane area less than the plane area of the source electrode 35. The gate electrode 40 has a plane area less than the plane area of the first pad portion 35a. The gate electrode 40 may have a plane area less than the plane area of the second pad portion 35b (third pad portion 35c).

The gate electrode 40 partially faces the plurality of gate structures 15 across the interlayer film 31. In detail, the gate electrode 40 is disposed at an interval inward from both end portions of the plurality of gate structures 15, and faces an inner portion (in this preferred embodiment, intermediate portion) of the plurality of gate structures 15 across the interlayer film 31. The gate electrode 40 does not have a direct electrical connection place with respect to the plurality of gate structures 15 in this preferred embodiment. As a matter of course, the gate electrode 40 may be electrically connected to the plurality of gate structures 15 through the plurality of gate openings 33.

Referring to FIG. 1, the semiconductor device 1 includes a gate wiring 41 led out from the gate electrode 40 onto the first principal surface 3. The gate wiring 41 transmits the gate potential applied to the gate electrode 40 to other regions. The gate wiring 41 includes the lower electrode film 36 and the principal electrode film 37 that are laminated in that order from the chip 2 side in the same way as the source electrode 35 (gate electrode 40), although not shown.

Referring to FIG. 1, the gate wiring 41 is led out from the gate electrode 40 onto a portion of the interlayer film 31 which covers the first surface portion 8. The gate wiring 41 is routed in a band shape to a region between the peripheral edge of the first surface portion 8 and the source electrode 35. The gate wiring 41 has a portion that extends in a band shape in the first direction X and a portion that extends in a band shape in the second direction Y in the plan view. The gate wiring 41 is formed in a band shape with ends having four sides parallel to the peripheral edges of the first principal surface 3, and surrounds the source electrode 35 in this preferred embodiment. The gate wiring 41 enters the plurality of gate openings 33 from above the interlayer film 31, and is mechanically and electrically connected to the end portion (both end portions) of the plurality of gate structures 15 in the plurality of gate openings 33. Thus, the gate potential applied to the gate electrode 40 is applied to the plurality of gate structures 15 through the gate wiring 41.

Referring to FIG. 2, FIG. 5, etc., the semiconductor device 1 includes a drain electrode 42 covering the second principal surface 4. The drain electrode 42 is a terminal electrode to which a drain potential is applied from the outside. The drain electrode 42 is electrically connected to the first semiconductor region 6. The drain electrode 42 may cover the whole area of the second principal surface 4 such as to be continuous with the peripheral edges of the second principal surface 4 (first to fourth side surfaces 5A to 5D). The drain electrode 42 may partially cover the second principal surface 4 such as to expose the peripheral edge portion of the second principal surface 4.

The breakdown voltage that is applicable between the source electrode 35 and the drain electrode 42 (between the first principal surface 3 and the second principal surface 4) may be not less than 500V and not more than 3000V. The breakdown voltage may have a value falling within at least one range among not less than 500V and not more than 1000V, not less than 1000V and not more than 1500V, not less than 1500V and not more than 2000V, not less than 2000V and not more than 2500V, and not less than 2500V and not more than 3000V.

Therefore, according to the preferred embodiment of this disclosure, the semiconductor device 1 includes the chip 2, the n-type second semiconductor region 7, the trench type gate structure 15, and the p-type well region 22. The chip 2 has the first principal surface 3. The second semiconductor region 7 is formed at the surface layer portion of the first principal surface 3. The gate structure 15 is formed on the first principal surface 3, and is placed in the second semiconductor region 7. The well region 22 is formed in the region (first lower region 61 and second lower region 62) below the gate structure 15 in the second semiconductor region 7. The well region 22 is formed along the second direction Y.

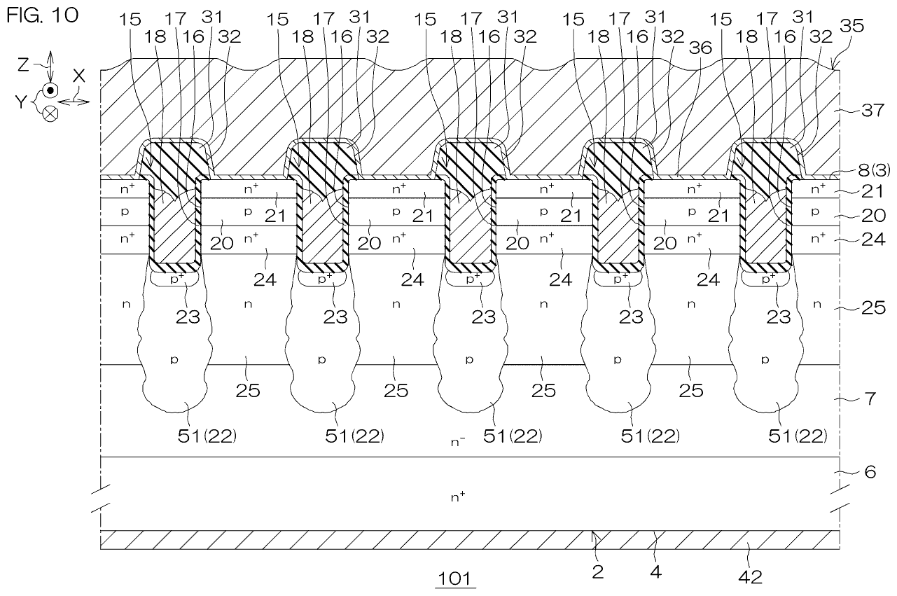

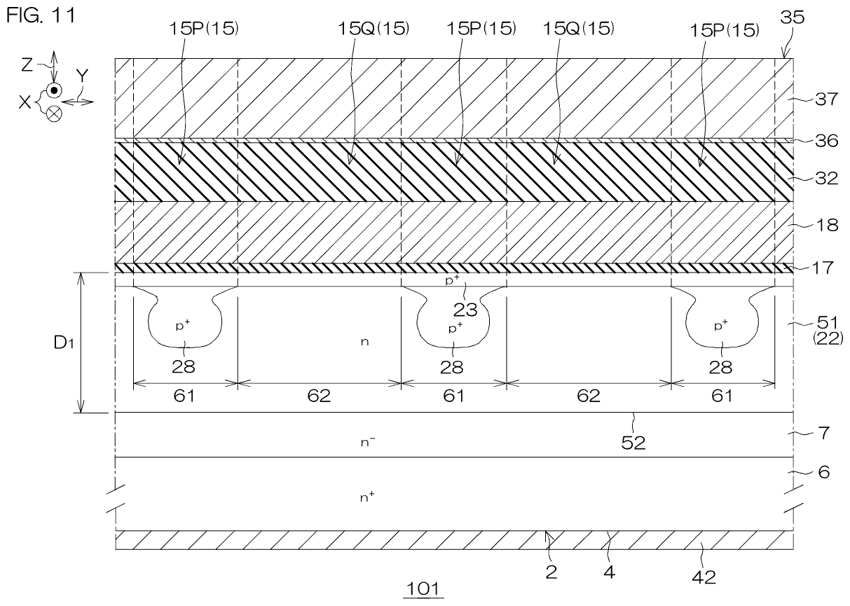

If the whole area of the well region 22 has the same first depth D₁ (see FIG. 11) in the same way as a semiconductor device 101 according to a reference example shown in FIG. 10 and FIG. 11, there is a concern that the current path of JFET will be pressed and that resistance (on-resistance or JFET resistance) will rise.

On the other hand, in this preferred embodiment, the well region 22 includes the plurality of first well regions 51 having the first bottom portion 52 having the first depth D₁. The plurality of first well regions 51 are formed at an interval of the first interval W₁ from each other in the second direction Y. The first well regions 51 adjacent each other face each other in the second direction Y across the sandwiched portion 7a as shown in FIG. 7.

The first well region 51 is formed in the region (first lower region 61) below the gate structure 15. An increase in current density near the bottom wall 15c of the gate structure 15 is suppressed by the first well region 51. This makes it possible to relax an electric field with respect to the bottom wall 15c of the gate structure 15, suppressing a decrease in withstand voltage due to concentration of electric field.

Additionally, the sandwiched portion 7a that is a portion of both the intermediate-concentration region 25 and the second semiconductor region 7 is interposed between the first well regions 51 adjacent each other. This sandwiched portion 7a functions as a current path. Therefore, it is possible to sufficiently secure the current path in the region (first lower region 61) below the gate structure 15. This makes it possible to reduce on-resistance and JFET resistance.

Therefore, it is possible to reduce resistance while suppressing a decrease in withstand voltage. In other words, the semiconductor device 1 that is capable of improving electrical properties is provided.

Preferably, the chip 2 includes SiC. With this configuration, the semiconductor device 1 is provided as an SiC semiconductor device that is capable of improving electrical properties. The first interval W₁ between the first well regions 51 adjacent each other may be larger than the first depth D₁ of the first bottom portion 52 of the first well region 51. With this configuration, it is possible to secure the current path more widely.

The well region 22 may include the first well region 51 and the second well region 53 that differ from each other in the depth of the bottom portion in the region (first lower region 61 and second lower region 62) below the gate structure 15. The first well region 51 and the second well region 53 may be continuous with each other. With this configuration, the first well region 51 and the second well region 53 are respectively formed in the regions (first lower region 61 and second lower region 62) below the gate structure 15. An increase in current density near the bottom wall 15c of the gate structure 15 is suppressed by both the first well region 51 and the second well region 53. This makes it possible to relax an electric field with respect to the bottom wall 15c of the gate structure 15, suppressing a decrease in withstand voltage due to concentration of electric field. Therefore, it is possible to reduce resistance (on-resistance or JFET resistance) while further suppressing a decrease in withstand voltage.

The second well region 53 may have the second depth D₂ shallower than the first depth D With this configuration, it is possible to relax an electric field with respect to the bottom wall 15c of the gate structure 15, further suppressing a decrease in withstand voltage due to concentration of electric field.

The ratio (D₂/D₂) of the second depth D₂ of the second bottom portion 54 of the second well region 53 with respect to the first depth D₁ of the first bottom portion 52 of the first well region 51 may be less than 0.5. With this configuration, the second depth D₂ of the second bottom portion 54 of the second well region 53 is sufficiently shallow, and therefore it is possible to largely secure a thickness T_{U} (see FIG. 7) of the sandwiched portion 7a formed below the second well region 53. This makes it possible to even more sufficiently secure the current path.

The first bottom portion 52 of the first well region 51 may have the first depth D₁ larger than the thickness T_{B} of the body region 20. The second well region 53 may have the second depth D₂ smaller than the thickness T_{B} of the body region 20. With this configuration, the second depth D₂ of the second bottom portion 54 of the second well region 53 is sufficiently shallow, and therefore it is possible to largely secure the thickness T_{U} (see FIG. 7) of the sandwiched portion 7a formed below the second well region 53. This makes it possible to even more sufficiently secure the current path.

The first bottom portion 52 of the first well region 51 may penetrate through the intermediate-concentration region 25, and may be placed in the second semiconductor region 7. The second well region 53 may have the second bottom portion 54 placed in the intermediate-concentration region 25. With this configuration, the second depth D₂ of the second bottom portion 54 of the second well region 53 is sufficiently shallow, and therefore it is possible to largely secure the thickness T_{U} (see FIG. 7) of the sandwiched portion 7a formed below the second well region 53. This makes it possible to even more sufficiently secure the current path.

Additionally, in this preferred embodiment, the sandwiched portion 7a sandwiched between the first well regions 51 adjacent each other is formed in the second lower region 62 below the second portion (portion in which the channel region 26 is formed) 15Q of the gate structure 15. The sandwiched portion 7a that is a portion of the drift region (the intermediate-concentration region 25 and the second semiconductor region 7) is interposed, and therefore it is possible to widely secure the current path in the second lower region 62 that is a channel lower region.

Additionally, in this preferred embodiment, the sandwiched portion 7a is not formed in the first lower region 61 below the first portion (region in which the channel region 26 is not formed) 15P of the gate structure 15. The amount of electric current that flows to the first lower region 61 that is a non-channel lower region is smaller than the second lower region 62 that is a channel lower region. Therefore, large resistance (on-resistance or JFET resistance) is not generated even if the width of the current path becomes narrower in the first lower region 61 that is a non-channel lower region. The first well region 51 is formed in the first lower region 61 that is a non-channel lower region, and therefore it is possible to suppress an increase in the current density near the bottom wall 15c of the gate structure 15. This makes it possible to relax an electric field with respect to the bottom wall 15c of the gate structure 15, effectively suppressing a decrease in withstand voltage due to concentration of electric field.

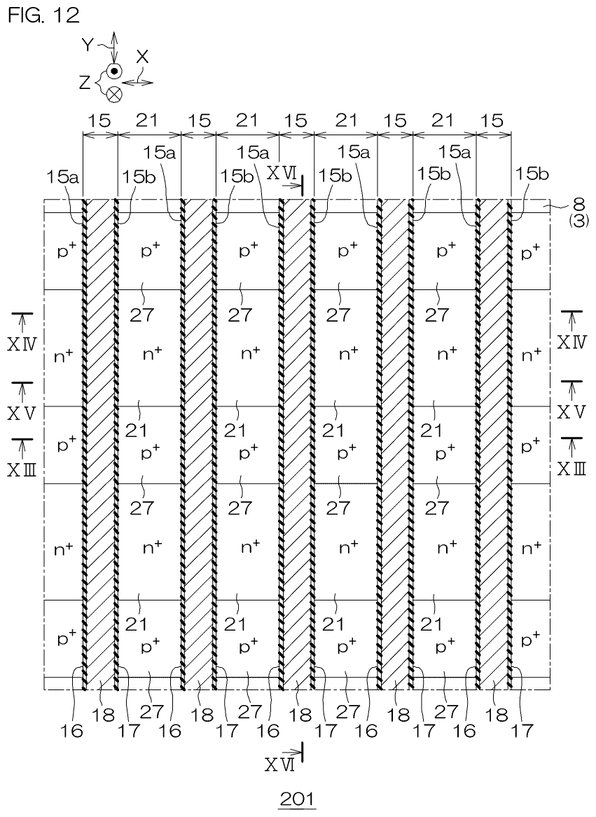

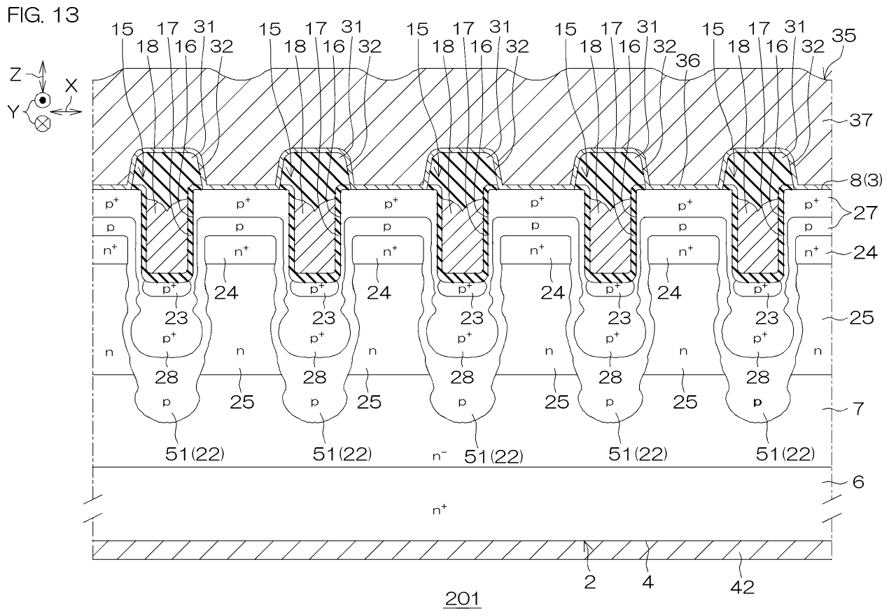

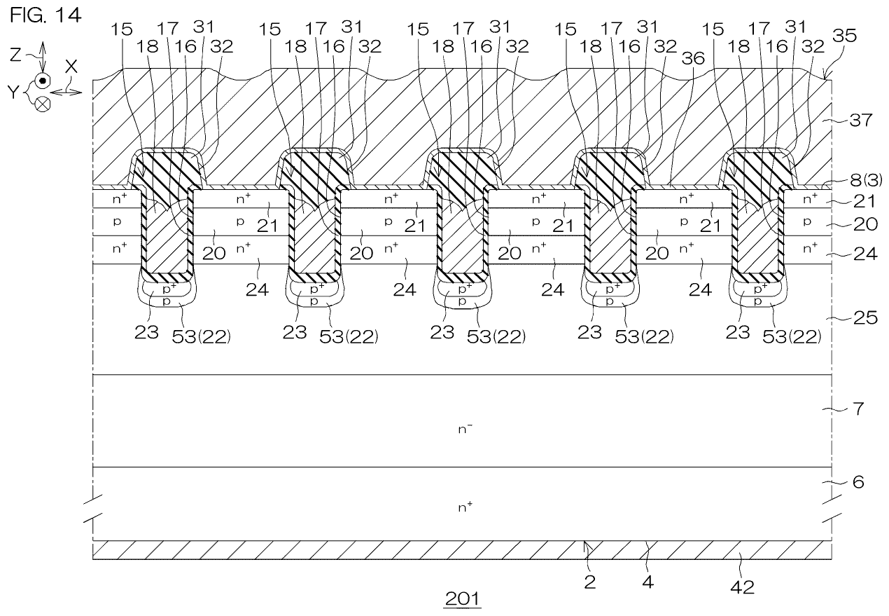

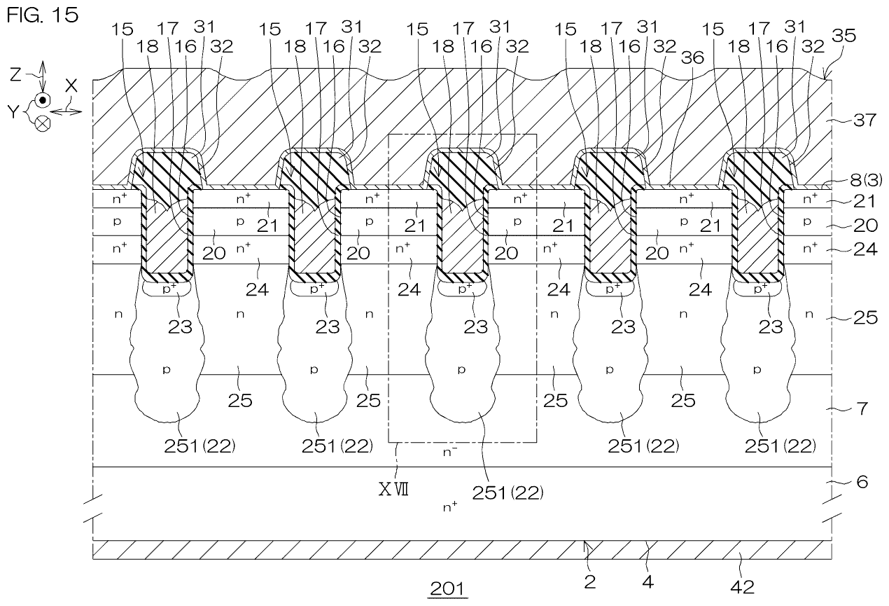

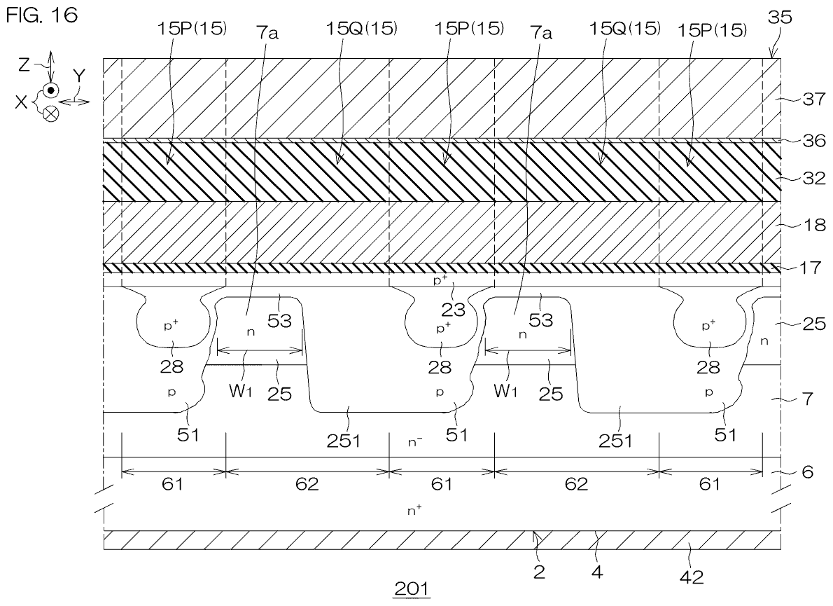

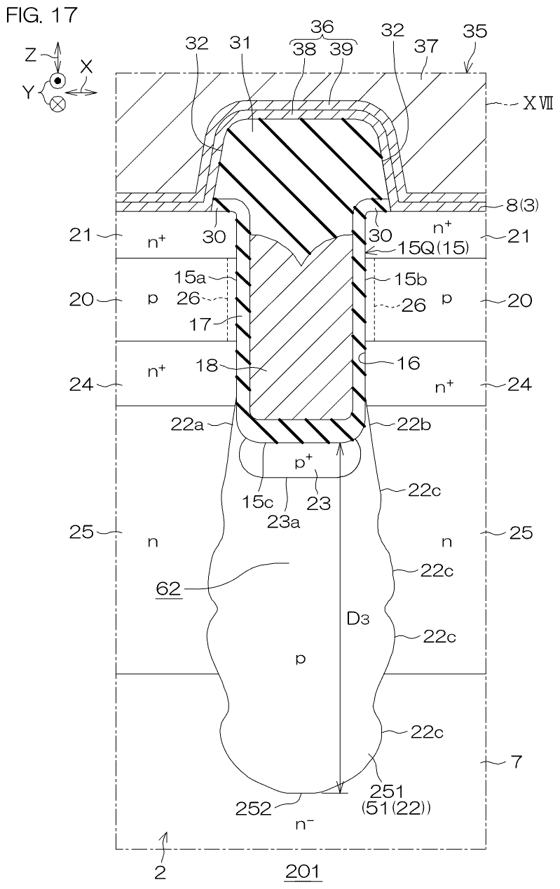

FIG. 12 is a plan view showing a layout example of a chip 2 according to a second preferred embodiment of the present disclosure, which corresponds to FIG. 4. FIG. 13 is a cross-sectional view taken along line XIII-XIII shown in FIG. 12. FIG. 14 is a cross-sectional view taken along line XIV-XIV shown in FIG. 12. FIG. 15 is a cross-sectional view taken along line XV-XV shown in FIG. 12. FIG. 16 is a cross-sectional view taken along line XVI-XVI shown in FIG. 12. FIG. 17 is an enlarged view of a portion surrounded by an alternate long and short dash line XVII of FIG. 15. In FIG. 12 to FIG. 17, the same reference sign is assigned to the same constituent as each constituent that has been hereinbefore described, and a description of the constituent is omitted.

A semiconductor device 201 according to the second preferred embodiment of the present disclosure differs from the semiconductor device 1 in the fact that the first well region 51 is formed in the second lower region 62 together with the first lower region 61. In the semiconductor device 201, the first well region 51 includes a region formed in the second lower region 62. In detail, the first well region 51 has a first region 251 formed in the second lower region 62 (see FIG. 15 to FIG. 17). The first region 251 comes into contact with the sandwiched portion 7a from one side in the second direction Y.

Referring to FIG. 15 to FIG. 17, the first region 251 has a third bottom portion 252. The third bottom portion 252 has a third depth D₃ (see FIG. 17). The third depth D₃ is the depth of the third bottom portion 252 of the first region 251 based on the bottom wall 15c of the gate structure 15. The third depth D₃ is larger than the thickness T_{B} of the body region 20 (D₃>T_{B}) (see FIG. 9). In this preferred embodiment, the third depth D₃ is equal to the first depth D₁ (see FIG. 8). As a matter of course, the third depth D₃ may differ in depth from the first depth D₁.

In other words, in the semiconductor device 201, the sandwiched portion 7a is formed not in the whole area of the second lower region 62 but in a portion of the second lower region 62.

Referring to FIG. 17, the first region 251 has one or a plurality of (in this preferred embodiment, a plurality of) first bulging portions 22c. In this preferred embodiment, the first region 251 includes neither the first extension portion 22a (see FIG. 9) nor the second extension portion 22b (see FIG. 9). As a matter of course, the first region 251 may include the first extension portion 22a and the second extension portion 22b.

With the semiconductor device 201 according to the second preferred embodiment of the present disclosure, the same operational effect equivalent to the operational effect described in relation to the first preferred embodiment is fulfilled.

Additionally, the sandwiched portion 7a is formed not in the whole area of the second lower region 62 but in the portion of the second lower region 62, and therefore it is possible to adjust the first interval W₁ between the first well regions 51 adjacent each other (see FIG. 16). The length in the second direction Y of the sandwiched portion 7a coincides with the first interval W₁ between the first well regions 51 adjacent each other (see FIG. 16) as described above. It is possible to adjust saturation current at ON time (channel formation time) to an optimal value by adjusting the first interval W₁ (see FIG. 16).

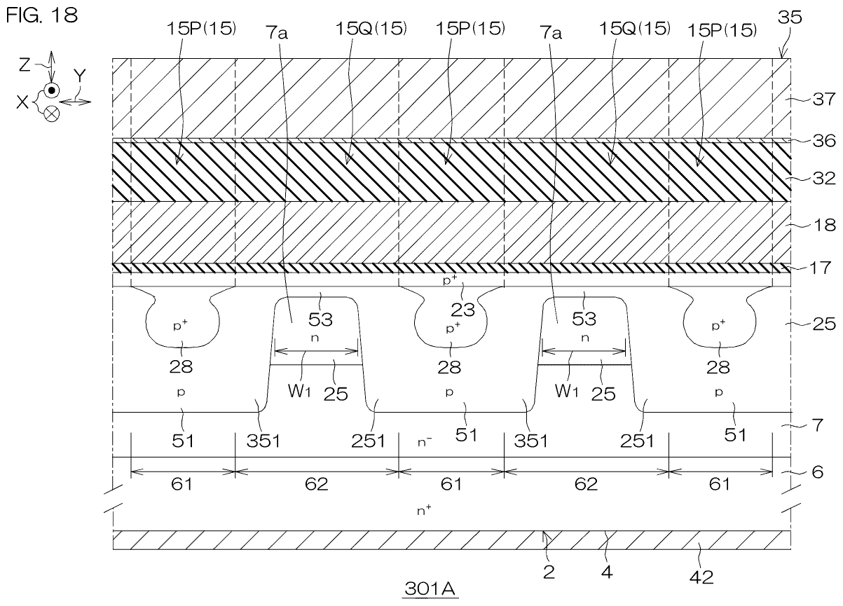

Referring to FIG. 18 to FIG. 27, semiconductor devices 301A, 301B, 301C, 301D, 301E, and 301F according to first to sixth modification examples will be hereinafter described. In FIG. 18 to FIG. 27, the same reference sign is assigned to the same constituent as each constituent that has been hereinbefore described, and a description of the constituent is omitted.

FIG. 18 is a cross-sectional view of the semiconductor device 301A according to the first modification example, which corresponds to FIG. 16. Referring to FIG. 18, the semiconductor device 301A according to the first modification example differs from the semiconductor device 201 in the fact that the first well region 51 includes a second region 351 together with the first region 251 in the second lower region 62. The second region 351 comes into contact with the sandwiched portion 7a from the other side in the second direction Y. The second region 351 has the same configuration as the first region 251.

The sandwiched portion 7a is formed not in the whole area of the second lower region 62 but in the portion of the second lower region 62, and therefore it becomes possible to adjust the first interval W₁ between the first well regions 51 adjacent each other in the same way as the semiconductor device 201 according to the second preferred embodiment. The length in the second direction Y of the sandwiched portion 7a coincides with the first interval W₁ (see FIG. 18) between the first well regions 51 adjacent each other as described above. It is possible to adjust saturation current at ON time (channel formation time) to an optimal value by adjusting the first interval W₁ (see FIG. 18).

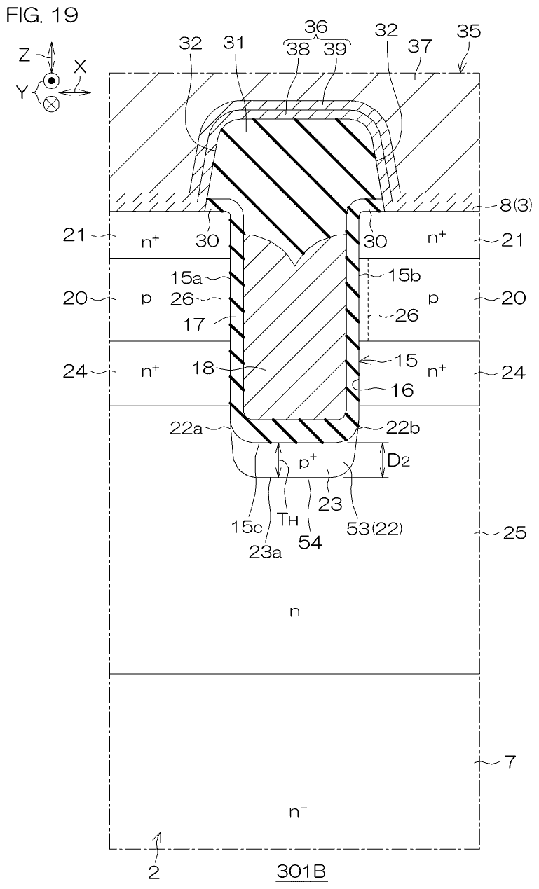

FIG. 19 is a cross-sectional view of the semiconductor device 301B according to the second modification example, which corresponds to FIG. 9. Referring to FIG. 19, in the semiconductor device 301B according to the second modification example, the second bottom portion 54 of the second well region 53 is placed at a height equal to that of the bottom portion 23a of the high-concentration well region 23. The second depth D₂ of the second bottom portion 54 of the second well region 53 is the same size as the thickness T_{H} of the high-concentration well region 23. In other words, the high-concentration well region 23 is in contact with the intermediate-concentration region 25 (semiconductor region) in the vertical direction Z.

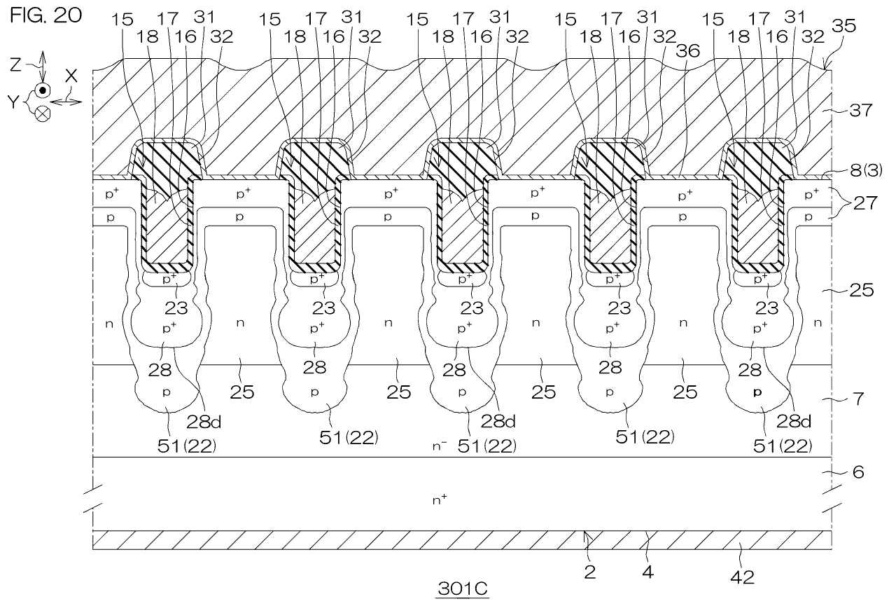

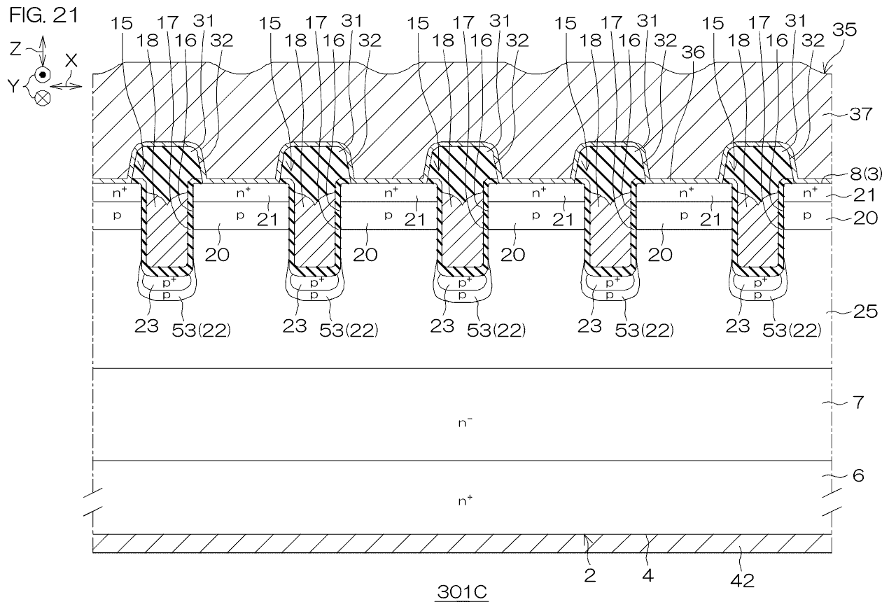

FIG. 20 is a cross-sectional view of the semiconductor device 301C according to the third modification example, which corresponds to FIG. 5. FIG. 21 is a cross-sectional view of the semiconductor device 301C according to the third modification example, which corresponds to FIG. 6. The semiconductor device 301C according to the third modification example differs from the semiconductor device 1 in the fact that the high-concentration region 24 has been excluded. The region in which the high-concentration region 24 is formed in the semiconductor device 1 has been replaced with the intermediate-concentration region 25 in the semiconductor device 301C. In this case, the plurality of channel regions 26 (see FIG. 9) are respectively formed between the plurality of source regions 21 and the plurality of intermediate-concentration regions 25 in the plurality of body regions 20. The plurality of channel regions 26 form current paths that connect the plurality of source regions 21 and the plurality of intermediate-concentration regions 25 along the side walls (first side wall 15a and second side wall 15b) of the plurality of gate structures 15 in the plurality of body regions 20, respectively.

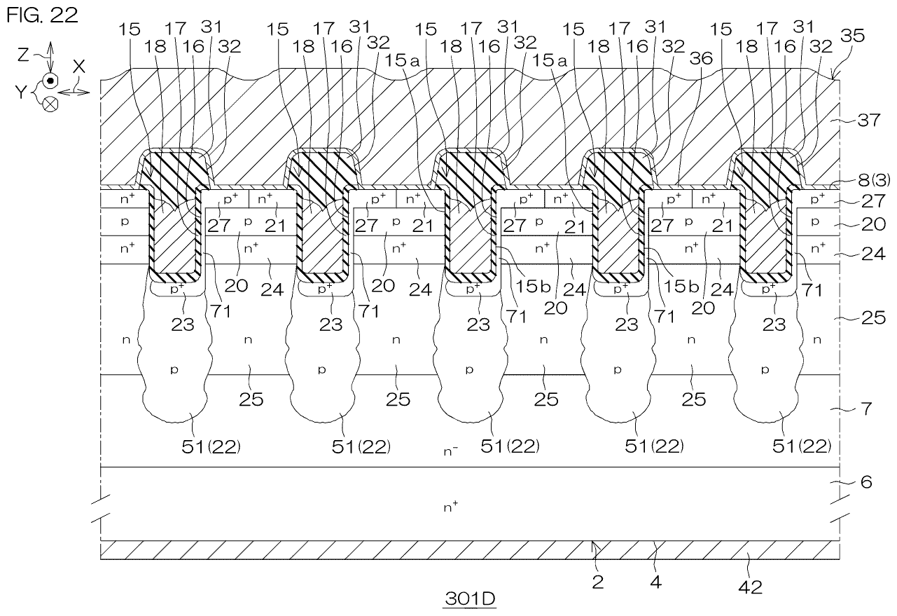

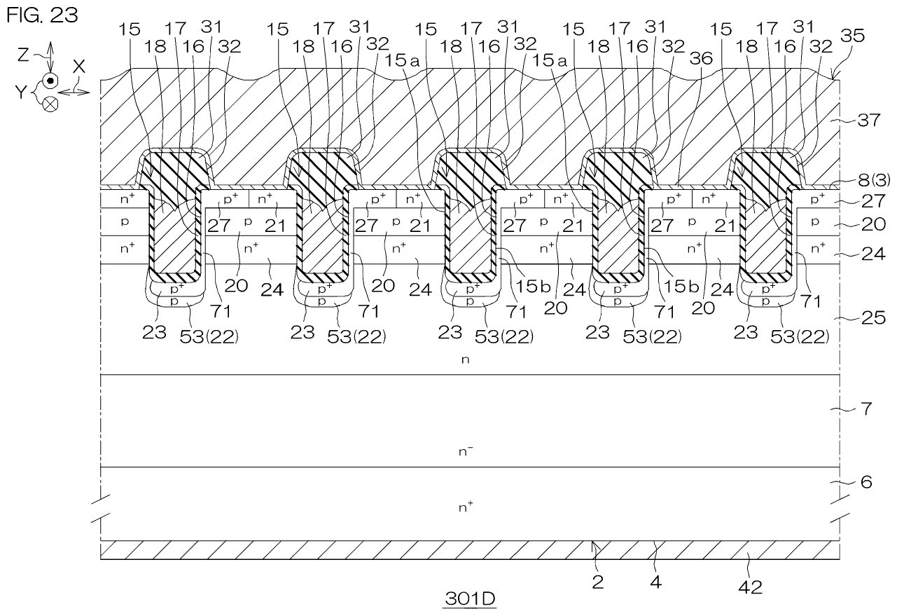

FIG. 22 is a cross-sectional view of the semiconductor device 301D according to the fourth modification example. FIG. 23 is a cross-sectional view of the semiconductor device 301D according to the fourth modification example. FIG. 22 and FIG. 23 are cross-sectional views obtained by cutting the semiconductor device 301D at different positions in the second direction Y.

In the fourth modification example, the source region 21 is selectively formed on the first side wall 15a side at an interval from the second side wall 15b of the gate structure 15 on one side in the first direction X in a region (mesa portion) sandwiched between the gate structures 15 adjacent each other. On the other hand, the first contact region 27 is adjacent to the source region 21 in the width direction (first direction X) of the region (mesa portion) sandwiched between the gate structures 15 adjacent each other, and is selectively formed on the second side wall 15b side. The source region 21 and the first contact region 27 are formed in a stripe shape extending in the second direction Y.

A third contact region 71 is selectively formed on one side of the region (mesa portion) sandwiched between the gate structures 15 adjacent each other. The third contact region 71 extends in the vertical direction Z along the first side wall 15a, and connects the first contact region 27 and the high-concentration well region 23 together.

The well region 22 functioning as a field relaxation layer includes the first well region 51 (see FIG. 22) formed below the high-concentration well region 23. The well region 22 includes the second well region 53 (see FIG. 23) formed below the high-concentration well region 23. The first well region 51 (see FIG. 22) and the second well region 53 (see FIG. 23) are alternately formed in the second direction Y.

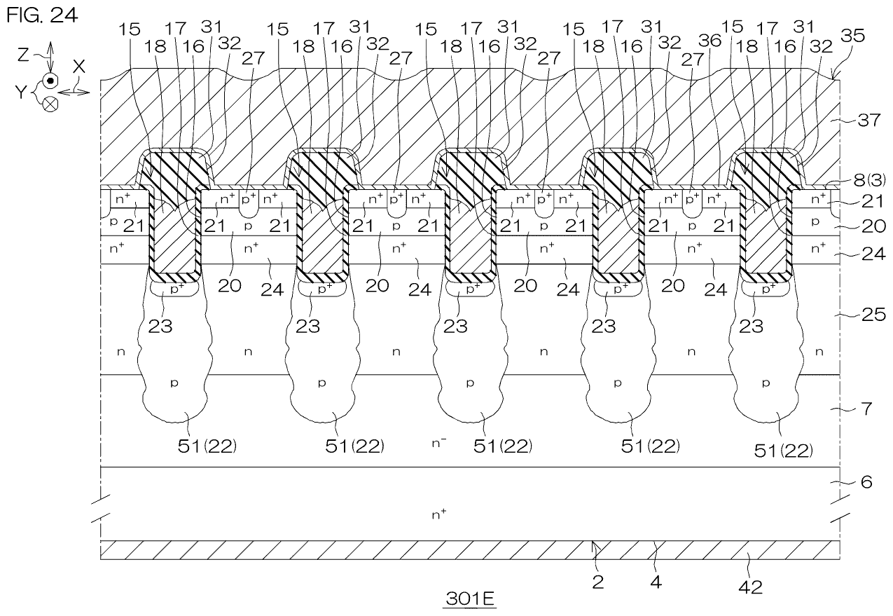

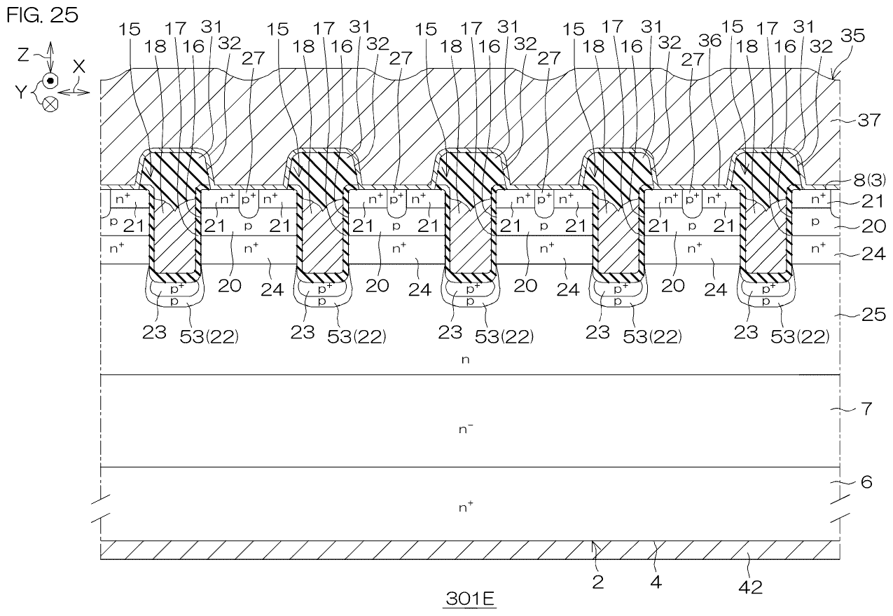

FIG. 24 is a cross-sectional view of the semiconductor device 301E according to the fifth modification example. FIG. 25 is a cross-sectional view of the semiconductor device 301E according to the fifth modification example. FIG. 24 and FIG. 25 are cross-sectional views obtained by cutting the semiconductor device 301E at different positions in the second direction Y.

In the fifth modification example, the source region 21 is formed on both sides of the gate structure 15 side that is one side in the first direction X and the gate structure 15 side that is the other side in the first direction X in the region (mesa portion) sandwiched between the gate structures 15 adjacent each other. In this modification example, a pair of band-shaped source regions 21 extend in a stripe shape in the second direction Y in the region (mesa portion) sandwiched between the gate structures 15 adjacent each other.

Additionally, the first contact region 27 is formed between the pair of source regions 21 in a central portion in the first direction X of the region (mesa portion) sandwiched between the gate structures 15 adjacent each other. The first contact region 27 is sandwiched between the pair of source regions 21 in the first direction X. The first contact region 27 penetrates through the source region 21 in the vertical direction Z, and is connected to the body region 20. The first contact region 27 extends in a band shape in the second direction Y in the region (mesa portion) sandwiched between the gate structures 15 adjacent each other. The first contact region 27 and the pair of source regions 21 between which the first contact region 27 is sandwiched from both sides are formed in a stripe shape extending in the second direction Y in the region (mesa portion) sandwiched between the gate structures 15 adjacent each other.

The well region 22 functioning as a field relaxation layer includes the first well region 51 (see FIG. 24) formed below the high-concentration well region 23. The well region 22 includes the second well region 53 (see FIG. 25) formed below the high-concentration well region 23. The first well region 51 (see FIG. 24) and the second well region 53 (see FIG. 25) are alternately formed in the second direction Y.

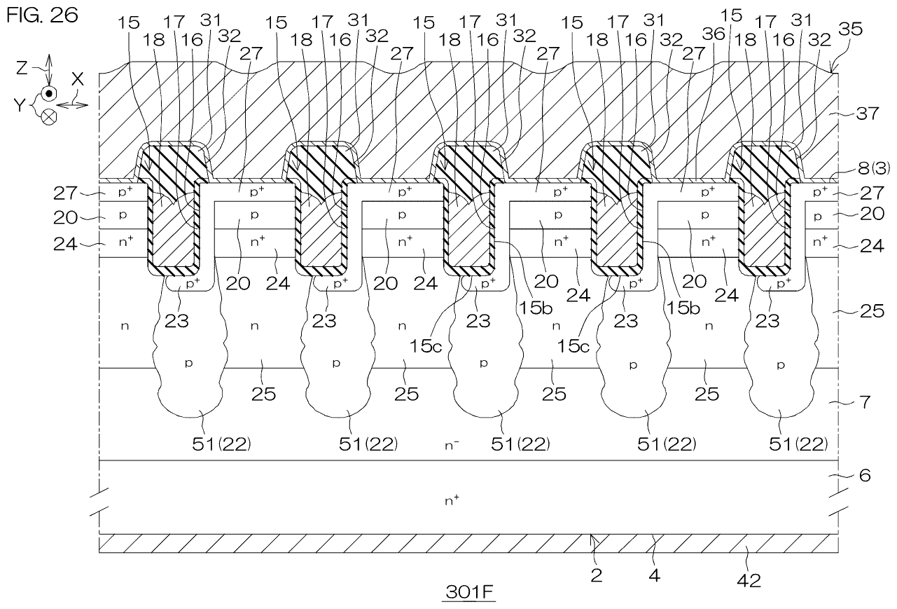

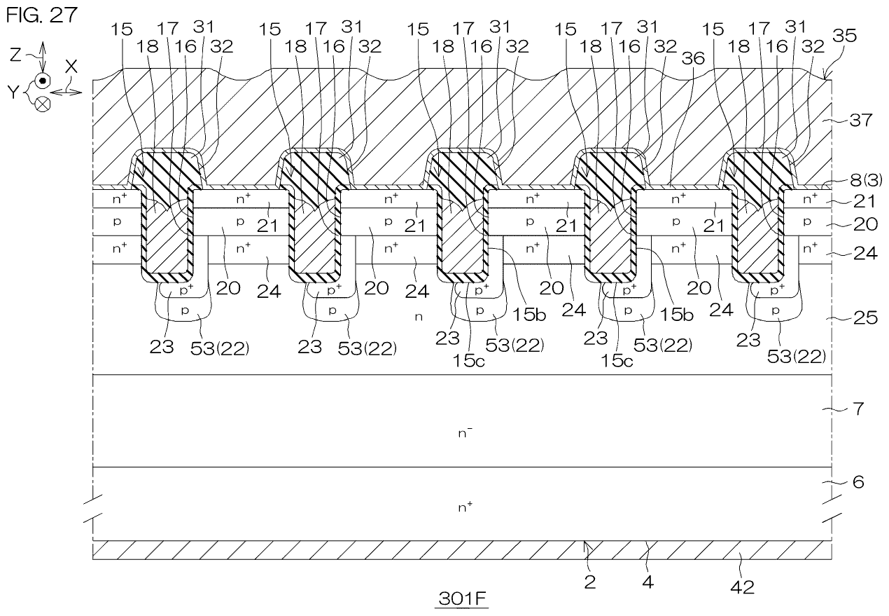

FIG. 26 is a cross-sectional view of the semiconductor device 301F according to the sixth modification example, which corresponds to FIG. 5. FIG. 27 is a cross-sectional view of the semiconductor device 301F according to the sixth modification example, which corresponds to FIG. 6.

In the sixth modification example, the well region 22 and the high-concentration well region 23 are formed such as to be placed, from an end portion on one side of the gate structure 15, closer to the other side in the first direction X. More specifically, the high-concentration well region 23 is selectively formed on the other side in the first direction X with respect to the gate structure 15. In this modification example, the high-concentration well region 23 extends downwardly from a portion of the body region 20 in the vertical direction Z in the region (mesa portion) sandwiched between the gate structures 15 adjacent each other, and expands in the horizontal direction along the first principal surface 3, and overlaps with the bottom wall 15c of the gate structure 15.

The high-concentration well region 23 forms at least a portion of the second side wall 15b of the gate structure 15 and at least a portion of the bottom wall 15c of the gate structure 15, and is in contact with the insulating film 17. The high-concentration well region 23 has a substantially L-shaped exposed surface that is exposed as a lower portion of the second side wall 15b and as the bottom wall 15c.

The well region 22 functioning as a field relaxation layer includes the first well region 51 (see FIG. 26) formed below the high-concentration well region 23. The well region 22 includes the second well region 53 (see FIG. 27) formed below the high-concentration well region 23. The first well region 51 (see FIG. 26) and the second well region 53 (see FIG. 27) are alternately formed in the second direction Y.

The first conductivity type may be a p-type, and the second conductivity type may be an n-type although an example in which the first conductivity type is an n-type and the second conductivity type is a p-type has been described in each of the aforementioned preferred embodiments (including the modification examples). A concrete configuration in this case can be obtained by replacing the n-type region with the p-type region and by replacing the p-type region with the n-type region in the foregoing description and in the accompanying drawings.

The chip 2 including the SiC monocrystal has been employed in each of the aforementioned preferred embodiments (including the modification examples). However, the chip 2 may include a wide bandgap semiconductor monocrystal other than the SiC monocrystal. The wide bandgap semiconductor is a semiconductor having a bandgap large than the bandgap of silicon. For example, the chip 2 may include gallium nitride, gallium oxide, diamond, etc. As a matter of course, the chip 2 may include a silicon monocrystal.

Likewise, the first semiconductor region 6 may include a wide bandgap semiconductor monocrystal other than the SiC monocrystal. The first semiconductor region 6 may include gallium nitride, gallium oxide, diamond, etc. As a matter of course, the first semiconductor region 6 may include a silicon monocrystal.

Likewise, the second semiconductor region 7 may include a wide bandgap semiconductor monocrystal other than the SiC monocrystal. The second semiconductor region 7 may include gallium nitride, gallium oxide, diamond, etc. As a matter of course, the second semiconductor region 7 may include a silicon monocrystal.

A p-type collector region may be formed at the surface layer portion of the second principal surface 4 of the chip 2 in each of the aforementioned preferred embodiments (including the modification examples). In this case, the chip 2 may have a single layer structure constituted of an n-type semiconductor substrate. In this case, the transistor structure Tr includes an IGBT (Insulated Gate Bipolar Transistor) structure instead of an MISFET structure. A concrete configuration in this case can be obtained by replacing the “source” of the MISFET structure with an “emitter” of the IGBT structure and by replacing the “drain” of the MISFET structure with a “collector” of the IGBT structure in the foregoing description.

Characteristic examples extracted from this description and from the drawings are hereinafter shown. Hereinafter, the alphanumeric characters, etc., in parentheses represent the corresponding components, etc., in the embodiments described above, but are not intended to limit the scope of each clause to the embodiments. The “semiconductor device” according to the following clauses may be replaced with “SiC semiconductor device,” “wide bandgap semiconductor device,” “semiconductor switching device,” “MISFET device,” “IGBT device,” etc., if necessary.

### Appendix 1-1

A semiconductor device (1, 201, 301A, 301B, 301C, 301D, 301E, 301F) comprising:
a chip (2) having a principal surface;
a first conductivity type drift region (7) formed at a surface layer portion of the principal surface (3);
a trench electrode type gate structure (15) formed on the principal surface (3) such as to be placed in the drift region (7); and
a second conductivity type well region (22) formed along a bottom wall (15c) of the gate structure (15) in a region below the gate structure (15) in the drift region (7),
wherein the well region (22) includes a plurality of first well regions (51) each of which is a first well region (51) having a first bottom portion (52) having a first depth (D₁) and which are formed at an interval of a first interval (W₁) from each other in the depth direction (Y) of the gate structure (15), and
the first well regions (51) adjacent each other face each other in the depth direction (Y) of the gate structure (15) across a portion (7a) of the drift region (7, 25).

With this configuration, the well region (22) includes the plurality of first well regions (51) formed at an interval of the first interval (W₁) from each other in the depth direction (Y) of the gate structure (15) in the region below the gate structure (15). The first well regions (51) adjacent each other face each other in the depth direction (Y) of the gate structure (15) across the portion (7a) of the drift region (7, 25).

The first well region (51) is formed in the region below the gate structure (15). An increase in current density near the bottom wall (15c) of the gate structure (15) is suppressed by the first well region (51). This makes it possible to relax an electric field with respect to the bottom wall (15c) of the gate structure (15), suppressing a decrease in withstand voltage due to concentration of electric field.

The portion (7a) of the drift region (7, 25) is interposed between the first well regions (51) adjacent each other. This portion (7a) functions as a current path. Therefore, it is possible to sufficiently secure the current path in the region below the gate structure (15). This makes it possible to reduce resistance (on-resistance or JFET resistance).

Therefore, it is possible to reduce resistance while suppressing a decrease in withstand voltage. In other words, the semiconductor device (1, 201, 301A, 301B, 301C, 301D, 301E, 301F) that is capable of improving electrical properties can be provided.

### Appendix 1-2

The semiconductor device (1, 201, 301A, 301B, 301C, 301D, 301E, 301F) according to Appendix 1-1, wherein the chip (2) includes SiC.

### Appendix 1-3

The semiconductor device (1, 201, 301A, 301B, 301C, 301D, 301E, 301F) according to Appendix 1-1 or Appendix 1-2, wherein the first interval (W₁) is larger than the first depth (D₁) of the first well region (51).

### Appendix 1-4

The semiconductor device (1, 201, 301A, 301B, 301C, 301D, 301E, 301F) according to any one of Appendix 1-1 to Appendix 1-3, wherein the well region (22) further includes a second well region (53) that is formed such as to be continuous with the first well region (51) between the first well regions (51) adjacent each other and that has a second bottom portion (54) having a second depth (D₂) shallower than the first depth (D₁).

With this configuration, the well region (22) includes the first well region (51) and the second well region (53) that differ from each other in the depth of the bottom portion in the region below the gate structure (15). The first well region (51) and the second well region (53) are continuous with each other.

The first well region (51) and the second well region (53) are formed in the region below the gate structure (15). An increase in current density near the bottom wall (15c) of the gate structure (15) is suppressed by both the first well region (51) and the second well region (53). This makes it possible to relax an electric field with respect to the bottom wall (15c) of the gate structure (15), suppressing a decrease in withstand voltage due to concentration of electric field. Therefore, it is possible to reduce resistance (on-resistance or JFET resistance) while further suppressing a decrease in withstand voltage.

### Appendix 1-5

The semiconductor device (1, 201, 301A, 301B, 301C, 301D, 301E, 301F) according to Appendix 1-4, wherein a ratio (D₂/D₁) of the second depth (D₂) with respect to the first depth (D₁) is less than 0.5.

### Appendix 1-6

The semiconductor device (1, 201, 301A, 301B, 301C, 301D, 301E, 301F) according to Appendix 1-4 or Appendix 1-5, further comprising a body region (20) that is formed on the principal surface (3) side with respect to the drift region (7, 25) in the surface layer portion of the principal surface (3), and through which the gate structure (15) penetrates,
wherein the first depth (D₁) is larger than a thickness (T_{B}) of the body region (20), and the second depth (D₂) is smaller than the thickness (T_{B}) of the body region (20).

### Appendix 1-7

The semiconductor device (1, 201, 301A, 301B, 301C, 301D, 301E, 301F) according to Appendix 1-6,
wherein the body region (20) extends in the depth direction (Y) of the gate structure (15) along a side wall (15a, 15b) of the gate structure (15), and
the body region (20) is connected to the well region (22).

### Appendix 1-8

The semiconductor device (1, 201, 301A, 301C, 301D, 301E, 301F) according to any one of Appendix 1-4 to Appendix 1-7, further comprising a second conductivity type high-concentration well region (23) that is formed in the well region (22) at an interval from the first bottom portion (52) of the first well region (51) toward the bottom wall (15c) of the gate structure (15) and that has an impurity concentration higher than the well region (22),
wherein the second bottom portion (54) of the second well region (53) is placed in the drift region (7, 25), and
the high-concentration well region (23) has a bottom portion (23a) placed closer to the bottom wall (15c) of the gate structure (15) than to the second bottom portion (54) of the second well region (53).

### Appendix 1-9

The semiconductor device (201, 301A, 301B, 301C, 301D, 301E, 301F) according to any one of Appendix 1-4 to Appendix 1-8, further comprising a second conductivity type high-concentration well region (23) that is formed in the well region (22) at an interval from the first bottom portion (52) of the first well region (51) toward the bottom wall (15c) of the gate structure (15) and that has an impurity concentration higher than the impurity concentration of the well region (22),
wherein the high-concentration well region (23) has a bottom portion (23a) placed at a height equal to the height of the second bottom portion (54) of the second well region (53).

### Appendix 1-10

The semiconductor device (1, 201, 301A, 301B, 301C) according to any one of Appendix 1-1 to Appendix 1-9, further comprising a second conductivity type channel region (26) formed along the side wall (15a, 15b) of the gate structure (15),
wherein a sandwiched portion (7a) sandwiched between the first well regions (51) adjacent each other of the drift region (7, 25) is formed in a channel lower region (62) below a portion (15Q), in which the channel region (26) is formed, of the gate structure (15).

With this configuration, the sandwiched portion (7a) sandwiched between the first well regions (51) adjacent each other is formed in the channel lower region (62) below the portion (15Q), in which the channel region (26) is formed, of the gate structure (15). The sandwiched portion (7a) that is a portion of the drift region (7) is interposed, and therefore it is possible to widely secure the current path in the channel lower region (62).

### Appendix 1-11

The semiconductor device (1, 301B, 301C) according to Appendix 1-10, wherein the first well region (51) is not formed in the channel lower region (62).

### Appendix 1-12

The semiconductor device (201, 301A) according to Appendix 1-10, wherein the first well region (51) includes a region formed in the channel lower region (62).

### Appendix 1-13

The semiconductor device (201, 301A) according to Appendix 1-12, wherein the first well region (51) has a first region (251) coming into contact with the sandwiched portion (7a) from one side in the depth direction (Y) of the gate structure (15) in the channel lower region (62).

### Appendix 1-14

The semiconductor device (301A) according to Appendix 1-13, wherein the first well region (51) further has a second region (351) coming into contact with the sandwiched portion (7a) from the other side in the depth direction (Y) of the gate structure (15) in the first lower region (61).

### Appendix 1-15

The semiconductor device (1, 201, 301A, 301B, 301C) according to any one of Appendix 1-10 to Appendix 1-14, wherein the first well region (51) is formed in a non-channel lower region (61) below a region (15P), in which the channel region (26) is not formed, of the gate structure (15), and
the sandwiched portion (7a) is not formed in the non-channel lower region (61).

With this configuration, the sandwiched portion (7a) is not formed in the non-channel lower region (61) below the region (15P), in which the channel region (26) is not formed, of the gate structures (15). The amount of electric current that flows to the non-channel lower region (61) is smaller than the channel lower region (62). Therefore, large resistance (on-resistance or JFET resistance) is not generated even if the width of the current path becomes narrower in the non-channel lower region (61). The first well region (51) is formed in the non-channel lower region (61), and therefore it is possible to suppress an increase in the current density near the bottom wall (15c) of the gate structure (15). This makes it possible to relax an electric field with respect to the bottom wall (15c) of the gate structure (15), effectively suppressing a decrease in withstand voltage due to concentration of electric field.

### Appendix 1-16

The semiconductor device (1, 201, 301A, 301B, 301C) according to Appendix 1-15, wherein, in the non-channel lower region (61), the first well region (51) is formed in a whole area in the depth direction (Y) of the gate structure.

### Appendix 1-17

The semiconductor device (301D) according to any one of Appendix 1-1 to Appendix 1-9, comprising:
a chip (2) having a principal surface;
a first conductivity type drift region (7) formed at a surface layer portion of the principal surface (3);
a trench electrode type gate structure (15) formed on the principal surface (3) such as to be placed in the drift region (7); and
a second conductivity type well region (22) formed along a bottom wall (15c) of the gate structure (15) in a region below the gate structure (15) in the drift region (7),
wherein the gate structure (15) is formed in a stripe shape, and
in a region sandwiched between the gate structures (15) adjacent each other, a source region (21) is selectively formed on a side wall (15a) side on one side of the gate structure (15) on the other side at an interval from a side wall (15b) on the other side of the gate structure (15) on one side.

### Appendix 1-18

The semiconductor device (301E) according to any one of Appendix 1-1 to Appendix 1-9, comprising:
a chip (2) having a principal surface;
a first conductivity type drift region (7) formed at a surface layer portion of the principal surface (3);
a trench electrode type gate structure (15) formed on the principal surface (3) such as to be placed in the drift region (7); and
a second conductivity type well region (22) formed along a bottom wall (15c) of the gate structure (15) in a region below the gate structure (15) in the drift region (7),
wherein the gate structure (15) is formed in a stripe shape, and
in a region sandwiched between the gate structures (15) adjacent each other, a source region (21) is formed on both sides of a side wall (15b) on the other side of the gate structure (15) on one side and a side wall (15a) on one side of the gate structure (15) on the other side.

1. A semiconductor device comprising:
a chip having a principal surface;
a first conductivity type drift region formed at a surface layer portion of the principal surface;
a trench electrode type gate structure formed on the principal surface such as to be placed in the drift region; and
a second conductivity type well region formed along a bottom wall of the gate structure in a region below the gate structure in the drift region,
wherein the well region includes a plurality of first well regions each of which is a first well region having a first bottom portion having a first depth and which are formed at an interval of a first interval from each other in a depth direction of the gate structure, and
the first well regions adjacent each other face each other in the depth direction of the gate structure across a portion of the drift region.

2. The semiconductor device according to claim 1, wherein the chip includes SiC.

3. The semiconductor device according to claim 1, wherein the first interval is larger than the first depth of the first well region.

4. The semiconductor device according to claim 1 wherein the well region further includes a second well region that is formed such as to be continuous with the plurality of the first well regions between the plurality of the first well regions and that has a second bottom portion having a second depth shallower than the first depth.

5. The semiconductor device according to claim 4, wherein a ratio of the second depth with respect to the first depth is less than 0.5.

6. The semiconductor device according to claim 4, further comprising a body region that is formed on the principal surface side with respect to the drift region in the surface layer portion of the principal surface, and through which the gate structure penetrates,
wherein the first depth is larger than a thickness of the body region, and the second depth is smaller than the thickness of the body region.

7. The semiconductor device according to claim 6,
wherein the body region extends in the depth direction of the gate structure along a side wall of the gate structure, and
the body region is connected to the well region.

8. The semiconductor device according to claim 4, further comprising a second conductivity type high-concentration well region that is formed in the well region at an interval from the first bottom portion of the first well region toward the bottom wall of the gate structure and that has an impurity concentration higher than the well region,
wherein the second bottom portion of the second well region is placed in the drift region, and
the high-concentration well region has a bottom portion placed closer to the bottom wall of the gate structure than to the second bottom portion of the second well region.

9. The semiconductor device according to claim 4 further comprising a second conductivity type high-concentration well region that is formed in the well region at an interval from the first bottom portion of the first well region toward the bottom wall of the gate structure and that has an impurity concentration higher than the impurity concentration of the well region,
wherein the second bottom portion of the second well region is placed at a height equal to the height of a bottom portion of the high-concentration well region.

10. The semiconductor device according to claim 1, further comprising a second conductivity type channel region formed along the side wall of the gate structure,
wherein a sandwiched portion sandwiched between the first well regions adjacent each other of the drift region is formed in a channel lower region below a portion, in which the channel region is formed, of the gate structure.

11. The semiconductor device according to claim 10, wherein the first well region is not formed in the channel lower region.

12. The semiconductor device according to claim 10, wherein the first well region includes a region formed in the channel lower region.

13. The semiconductor device according to claim 12, wherein the first well region has a first region coming into contact with the sandwiched portion from one side in the depth direction of the gate structure in the channel lower region.

14. The semiconductor device according to claim 13, wherein the first well region further has a second region coming into contact with the sandwiched portion from the other side in the depth direction of the gate structure in the channel lower region.

15. The semiconductor device according to claim 10, wherein the first well region is formed in a non-channel lower region below a region, in which the channel region is not formed, of the gate structure, and
the sandwiched portion is not formed in the non-channel lower region.

16. The semiconductor device according to claim 15, wherein, in the non-channel lower region, the first well region is formed in a whole area in the depth direction of the gate structure.
